(19) United States
(12) Patent Application Publication
(10) Pub. No.: US 2024/0282588 A1
(43) Pub. Date: Aug. 22, 2024

(54) THREE-DIMENSIONAL CIRCUIT PART AND METHOD OF MANUFACTURING THREE-DIMENSIONAL CIRCUIT PART

(71) Applicant: MAXELL, LTD., Otokuni-gun, Kyoto (JP)

(72) Inventors: Akiko KITO, Otokuni-gun (JP); Atsushi YUSA, Otokuni-gun (JP); Satoshi YAMAMOTO, Otokuni-gun (JP); Hironori OTA, Otokuni-gun (JP)

(73) Assignee: MAXELL, LTD., Otokuni-gun, Kyoto (JP)

(21) Appl. No.: 18/565,732

(22) PCT Filed: Jun. 6, 2022
(86) PCT No.: PCT/JP2022/022757

§ 371 Date: Nov. 30, 2023

(30) Foreign Application Priority Data
Jun. 4, 2021 (JP) 2021-094143

(51) Int. Cl. H01L 21/48; H01L 21/56; H01L 21/768; H01L 23/373

(52) U.S. Cl. CPC H01L 21/4803; H01L 21/565; H01L 21/76837; H01L 21/76873; H01L 23/3736

(57) ABSTRACT

A circuit part that provides high heat dissipation is provided. A three-dimensional circuit part includes: a metal member; a first resin layer provided on top of the metal member; first circuit wiring including plating film provided on a wiring region of the surface of the first resin layer; and a first mounted component mounted on a mount region of the surface of the first resin layer to electrically connect to the first circuit wiring. In the surface of the first resin layer, the wiring region and the mount region overlap in an overlap region, and the surface roughness Rz of the overlap region is 10 μm to 120 μm; and the minimum distance between the first circuit wiring and the face of the first resin layer facing the metal member within the overlap region is 10 μm to 100 μm.

### TECHNICAL FIELD

The present invention relates to a three-dimensional circuit part and a method of manufacturing a three-dimensional circuit part.

### BACKGROUND ART

Molded interconnect devices (MIDs) have been commercialized for applications such as smartphones, and applications are expected to be expanded to the field of automobiles. An MID is a device composed of a resin molding with a circuit constituted by metal film on its surface, and can contribute to a reduction in the weight of the product, a reduction in wall thickness and a reduction in the number of parts.

MIDs with light-emitting diodes (LEDs) mounted thereon have also been proposed. When electric current flows through LEDs, they emit heat, which needs to be removed from the backside; as such, increasing the heat dissipation of an MID is important. Patent Document 1 proposes a composite part with a metallic heat-dissipating material integrated with the MID. Further, in the MID of Patent Document 1, the circuit wiring is formed from plating film.

### PRIOR ART DOCUMENTS

### Patent Documents

Patent Document 1: Japanese Patent No. 3443872

### SUMMARY OF THE INVENTION

In recent years, electronic devices with increasingly higher performance together with constantly reduced in size have been developed, accompanied by the development of MIDs used therein having higher density and higher functionality, which requires even higher heat dissipation. A heat dissipation material of an MID is constituted by a metal member; in an MID with a resin layer provided on a metal member, reducing the thickness of this resin layer is effective in improving heat conduction from the circuit wiring on the resin layer to the metal member. However, it is difficult to form a thin insulating resin layer with a uniform thickness on a three-dimensional surface of a metal member, for example, and thus there are limits on improving heat dissipation by only reducing the thickness of the resin layer.

Further, MIDs have been proposed that have a power device mounted thereon to pass large amounts of electric current. In such cases, to address the higher packaging density and the resulting narrower line width of the circuit wiring and, at the same time, to ensure heat dissipation, it is necessary to increase the thickness of the circuit wiring. However, in cases where the circuit wiring includes plating film, for example, it is impossible during plating to prevent the plating film from spreading in the line-width direction of the wiring, making it difficult to increase the density of the circuit.

The present invention solves these problems, and provides a three-dimensional circuit part that provides high heat dissipation and also enables increasing circuit density.

A first aspect of the present invention provides a three-dimensional circuit part including: a metal member; a first resin layer provided on top of the metal member; first circuit wiring including plating film provided on a wiring region of a surface of the first resin layer; and a first mounted component mounted on a mount region of the surface of the first resin layer to electrically connect to the first circuit wiring, wherein: in the surface of the first resin layer, the wiring region and the mount region overlap in an overlap region, and a surface roughness Rz of the overlap region is 10 μm to 120 μm; and a minimum distance between the first circuit wiring and a face of the first resin layer facing the metal member within the overlap region is 10 μm to 100 μm.

The surface roughness Rz of the overlap region may be higher than a surface roughness Rz of a portion of the wiring region other than the overlap region. The circuit part may further include: a second resin layer provided on a portion of the surface of the first resin layer other than the overlap region to cover the first circuit wiring, wherein a ratio of a surface roughness Rz of a portion of the wiring region other than the overlap region to the surface roughness Rz of the overlap region may be not higher than 1/2. The circuit part may further include: a second resin layer provided on a portion of the surface of the first resin layer other than the overlap region to cover the first circuit wiring; second circuit wiring including plating film provided on top of the second resin layer; and a second mounted component mounted on top of the second resin layer to electrically connect to the second circuit wiring. The first resin layer may contain a thermosetting resin, and the thermosetting resin may be an epoxy resin.

A surface roughness Ra of the overlap region may be higher than a surface roughness Ra of a portion of the wiring region other than the overlap region.

The metal member may be a product of sheet metal working. A material forming the product of sheet metal working may be one selected from the group consisting of aluminum, stainless steel, and copper.

A second aspect of the present invention provides a three-dimensional circuit part including: a metal member; a first resin layer provided on top of the metal member; first circuit wiring including plating film provided on a wiring region of a surface of the first resin layer; and a first mounted component mounted on a mount region of the surface of the first resin layer to electrically connect to the first circuit wiring, wherein: the first resin layer includes a multi-stage groove structure including a first groove formed in the wiring region and a second groove formed within the first groove and having a smaller width than the first groove; and the plating film of the first circuit wiring fills the multi-stage groove structure.

The plating film of the first circuit wiring includes a protrusion protruding outward from the multi-stage groove structure, wherein a height of the protrusion as measured from a portion of the surface of the first resin layer where the first circuit wiring is not present may be not larger than 30% of a film thickness of the plating film. Furthermore, the protrusion protrudes from the first groove in a line-width direction of the first circuit wiring to extend along the surface of the first resin layer, wherein a length of a portion of the protrusion that protrudes from the first groove in the line-width direction as measured along the surface of the first resin layer may be not larger than 30% of a line width of the first circuit wiring. Further, a ratio of a film thickness of the plating film of the first circuit wiring to a line width of the first circuit wiring may be 0.3 to 4. The film thickness of the plating film of the first circuit wiring may be 15 to 100 μm.

A third aspect of the present invention provides a method of manufacturing the three-dimensional circuit part of the first or second aspect, including: preparing the metal member; forming the first resin layer by shaping a first resin sheet on top of the metal member or applying a first resin liquid to the metal member; forming the first circuit wiring through plating on the wiring region of the surface of the first resin layer; and mounting the first mounted component on the mount region of the surface of the first resin layer.

The method may further include: before mounting the first mounted component, forming a second resin layer on a portion of the surface of the first resin layer other than the overlap region to cover the first circuit wiring, wherein the second resin layer may be formed by shaping a second resin sheet on top of the first resin layer or applying a second resin liquid to the first resin layer. Further, the second resin layer may be formed by applying the second resin liquid to the first resin layer.

The forming of the first circuit wiring may include: illuminating the wiring region with a laser beam to roughen the wiring region; providing the roughened wiring region with an electroless-plating catalyst; and forming electroless-plating film by bringing an electroless-plating solution into contact with the wiring region provided with the electroless-plating catalyst. The forming of the first circuit wiring may further include: before illuminating the wiring region with the laser beam, forming a layer containing a catalytic-activity inhibitor agent on the surface of the first resin layer inclusive of the wiring region, wherein a portion of the layer containing the catalytic-activity inhibitor agent located on the wiring region may be removed by illuminating the wiring region with the laser beam.

The forming of the first circuit wiring may include: forming a first groove in the wiring region through illumination with a laser beam or press working; forming a layer containing a catalytic-activity inhibitor agent on the surface of the first resin layer inclusive of the wiring region; forming a second groove with a smaller width than the first groove by directing a laser beam into the first groove; providing the wiring region with an electroless-plating catalyst; forming electroless-plating film within the second groove by bringing an electroless-plating solution into contact with the wiring region provided with the electroless-plating catalyst; and forming electroplating film on top of the electroless-plating film.

The preparing of the metal member may be forming the metal member through metal sheet working of a metal sheet. A material of the metal sheet may be one selected from the group consisting of aluminum, stainless steel, and copper.

A three-dimensional circuit part according to the present invention provides high heat dissipation and also enables increasing circuit density.

### BRIEF DESCRIPTION OF THE DRAWINGS

FIG. 1(a) is a schematic plan view of a circuit part according to a first embodiment, and FIG. 1(b) is a schematic cross-sectional view taken along line IB-IB of FIG. 1(a).

FIG. 2 is an enlarged schematic cross-sectional view taken along line II-II of FIG. 1(a).

FIG. 3 is a flow chart illustrating a method of manufacturing the circuit part according to the first embodiment.

FIG. 4 is a schematic cross-sectional view of a circuit part according to a second embodiment.

FIG. 5 is an enlarged schematic cross-sectional view taken along line V-V of FIG. 4.

FIG. 6 is a flow chart illustrating a method of manufacturing the circuit part according to the second embodiment.

FIG. 7(a) is a schematic plan view of a circuit part according to a third embodiment, and FIG. 7(b) is a schematic cross-sectional view taken along line VIIB-VIIB of FIG. 7(a).

FIG. 8 is a flow chart illustrating a method of manufacturing the circuit part according to the third embodiment.

FIG. 9 is a schematic cross-sectional view of a circuit part according to a fourth embodiment.

FIG. 10 is an enlarged view of portion X of FIG. 9.

FIGS. 11(a) to 11(d) illustrate a method of manufacturing the circuit part according to the fourth embodiment, corresponding to portion X of FIG. 9.

FIG. 12 shows the circuit part according to the fourth embodiment halfway through manufacturing as found after formation of electroplating film, corresponding to portion X of FIG. 9.

FIG. 13 is a schematic cross-sectional view of a circuit part according to a fifth embodiment.

FIGS. 14(a) to (c) illustrate a method of manufacturing the circuit part for Comparative Example 3, corresponding to portion X of FIG. 9.

### EMBODIMENTS FOR CARRYING OUT THE INVENTION

### First Embodiment

### <Circuit Part>

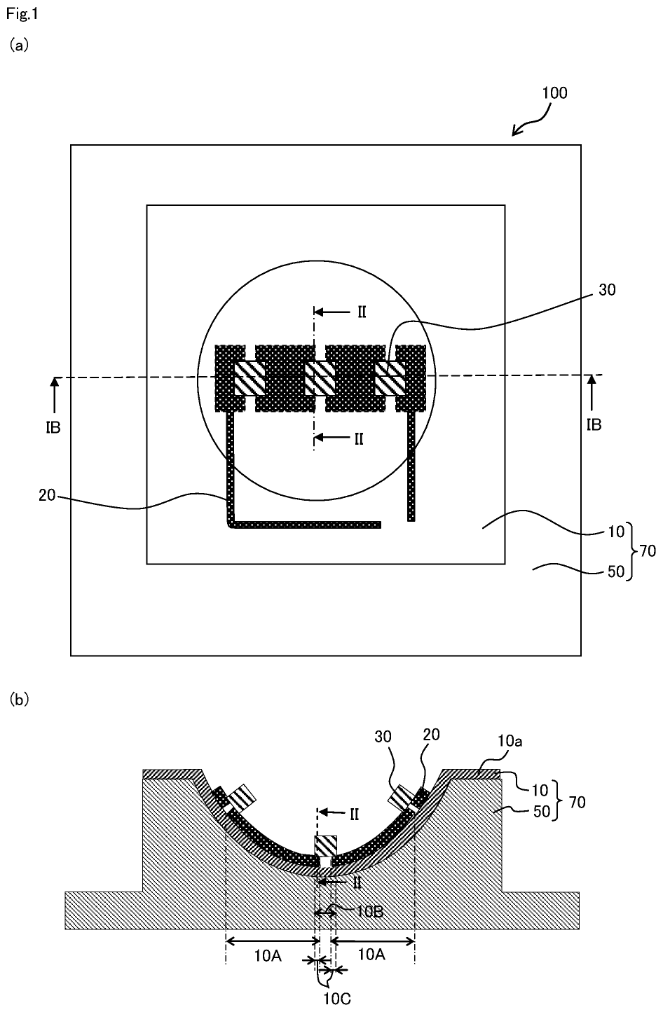

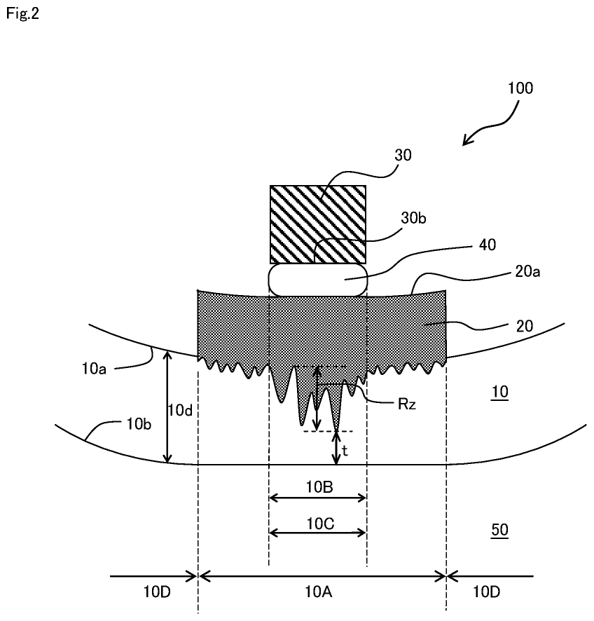

A circuit part 100 shown in FIGS. 1 and 2 will be described. The circuit 100 includes: a substrate 70 including a metal member 50 and a first resin layer 10; first circuit wiring 20 provided on top of the first resin layer 10 of the substrate 70; and a first mounted component 30 mounted on top of the first resin layer 10 to electrically connect to the first circuit wiring 20. It is to be understood that the circuit part 100 according to the present embodiment may be a three-dimensional circuit part (i.e., molded interconnect device (MID)). A three-dimensional circuit part is a circuit part with a circuit pattern that is three-dimensional in shape and formed on a plurality of faces of the substrate or along a three-dimensional face including a spherical face, for example. As shown in FIGS. 1 and 2, according to the present embodiment, the substrate 70 includes a curved face, on which three-dimensional first circuit wiring 20 is located. As such, the circuit part 100 according to the present embodiment is a three-dimensional circuit part.

The metal member 50 dissipates heat emitted by the first mounted component 30 mounted on the first resin layer 10. In view of this, it is preferable that the metal member 50 is made of a heat-dissipating metal, such as iron, copper, aluminum, titanium, magnesium, stainless steel (SUS), for example. Magnesium and aluminum are particularly preferable from the viewpoint of weight reduction, heat dissipation and cost. One of these metals may be used alone, or a mixture of two or more thereof may be used, or an alloy may be used. The thermal conductivity of the metal member 50 may be 80 to 300 W/m·K, for example.

The metal member 50 is not limited to any particular shape or size, and may be designed as desired depending on the application of the circuit part 100. For example, the metal member 50 may be sheet-shaped (i.e., a sheet metal), or may be radiating fins. Alternatively, the metal member 50 may have a complex shape created through cutting or die casting.

The first resin layer 10 has insulating properties to insulate the first circuit wiring 20 from the metal member 50 to prevent short circuit. In other words, the first resin layer 10 is an insulating resin layer. The degree of insulation of the first resin layer 10, although depending on the application of the circuit part 100, is preferably such that, for example, the resistance upon application of a voltage of 100 V between the first metal member 50 and the first circuit wiring 20 is not lower than 100 MΩ, not lower than 1000 MΩ, or above 10000 MΩ. Further, the withstand voltage between the metal member 50 and the first circuit wiring 20 is preferably not lower than 0.5 kV, not lower than 1 kV, or not lower than 1.5 kV. If the resistance between the first circuit wiring 20 and metal member 50 is too low or the withstand voltage therebetween is too low, fine current flows from the first circuit wiring 20 to the metal member 50 such that the first circuit wiring 20 cannot function anymore. The first circuit wiring 20 is sufficiently insulated from the metal member 50 if the resistance and/or withstand voltage between the first circuit wiring 20 and metal member 50 are in such ranges as set forth above. It is preferable that the first resin layer 10 is formed directly on top of the metal member 50. That is, the first resin layer 10 may be formed in contact with the surface of the metal member 50. This is thought to provide insulating properties generally equivalent to those provided by ceramics positioned between the first resin layer 10 and metal member 50, for example. Further, it increases shock resistance and eliminates some manufacturing steps such as the vacuum step for providing ceramics.

Further, to increase the heat dissipation of the circuit part 100, the first resin layer 10 preferably has some level of thermal conductivity. Thus, the first resin layer 10 is an insulating, heat-dissipating resin layer that provides both insulating properties and some level of thermal conductivity. The thermal conductivity of the first resin layer 10 may be, for example, 0.7 to 5 W/m·K, or 1 to 5 W/m·K. A thermal conductivity set forth herein is the thermal conductivity of the first resin layer 10 along its thickness direction, and may be measured by the laser flash method, for example. If the thermal conductivity is lower than the lower limit of such a range as set forth above, heat dissipation may decrease. If the thermal conductivity is to be higher than the upper limit of such a range, a large amount of insulating, thermally conductive filler, discussed further below, must be contained in the layer, for example, potentially making it difficult to form the first resin layer 10 through application, or causing other problems.

The first resin layer 10 contains a resin. If the first mounted component 30 is to be mounted on the first resin layer 10 through welding, the resin used for the first resin layer 10 is preferably a heat-resistant, high-melting-point resin that has solder-reflow resistance. The melting point of the resin used in the first resin layer 10 is preferably not lower than 260° C., and more preferably not lower than 290° C. This does not necessarily apply if the first mounted component 30 is to be mounted using a low-temperature solder.

The resin used in the first resin layer 10 may be, for example, a thermosetting resin, a thermoplastic resin, or an ultraviolet-curable resin. A thermosetting resin that is easy to form into a small thickness, provides high forming accuracy, and provides high heat resistance and high density after curing is particularly preferable. Examples of thermosetting resins that can be used include heat-resistant resins such as epoxy resins, silicone resins, and polyimide resins, where epoxy resins are particularly preferable. Examples of light-curable resins that can be used include polyimide resins and epoxy resins. Examples of thermoplastic resins that can be used include aromatic polyamides such as 6T nylon (6TPA), 9T nylon (9TPA), 10T nylon (10TPA), 12T nylon (12TPA), MXD6 nylon (MXDPA) and alloy materials thereof; polyphenylene sulfide (PPS), liquid crystal polymer (LCP), polyether ether ketone (PEEK), polyetherimide (PEI), and polyphenylsulfone (PPSU). One of these thermosetting resins, ultraviolet-curable resins and thermoplastic resins may be used alone, or a mixture of two or more thereof may be used. Such a resin or such resins may be the main ingredient(s) of the first resin layer 10. The amount of resin in the first resin layer 10 may be, for example, 20 to 100 weight %, or 50 to 100 weight %.

The first resin layer 10 may contain insulating, thermally conductive filler. The insulating thermally conductive filler is capable of improving the thermal conductivity of the first resin layer 10 while retaining its insulating properties. As used herein, “insulating thermally conductive filler” refers to a filler with a thermal conductivity not lower than 1 W/m·K, and excludes electrically conductive heat-dissipating materials such as carbon. Examples of insulating thermally conductive fillers include inorganic powders with high thermal conductivity, such as aluminum oxide, silicon oxide, magnesium oxide, magnesium hydroxide, boron nitride, aluminum nitride, and other ceramic powders. A rod-shaped filler such as wollastonite or a plate-shaped filler such as talc or boron nitride may be mixed therein to increase the contact ratio between filler particles and improve heat transfer. Alternatively, a scale-like, granular, or spherical filler may be used. One of these insulating thermally conductive fillers may be used alone, or a mixture of two or more thereof may be used.

The maximum diameter of insulating thermally conductive filler particles (i.e., maximum particle size) is preferably 30 μm to 100 μm, for example, if relatively cheap ceramic particles are used. If the thickness of the first resin layer 10 is to be reduced, the maximum diameter of insulating thermally conductive filler particles is preferably 10 μm to 60 μm.

The insulating thermally conductive filler may be contained in the first resin layer 10 in 10 weight % to 90 weight %, for example, and may be contained in 30 weight % to 80 weight %. If the amount of insulating thermally conductive filler is within such a range, the circuit part 100 provides sufficient heat dissipation.

The first resin layer 10 may further contain a rod-shaped or needle-shaped filler, such as glass fiber or calcium titanate, to regulate its strength. Furthermore, the first resin layer 10 may contain various common additives added to a resin molding, as necessary.

As shown in FIGS. 1(b) and 2, the surface 10a of the first resin layer 10 includes a wiring region 10A on which the first resin wiring 20 is to be formed, and a mount region 10B on which the first mounted component 30 is to be mounted. The first circuit wiring 20 is formed directly upon the surface 10a of the first resin layer 10. As such, the wiring region 10A is directly connected to the first circuit wiring 20. The first mounted component 30 is mounted above the mount region 10B with the first circuit wiring 20 and solder 40 positioned in between. As such, the first mounted component 30 need not be directly connected to the mount region 10B. The mount region 10B is located between the first mounted component 30 and the metal member 50 as determined in the direction perpendicular to the bottom surface 30b of the first mounted component 30 facing the substrate 70.

Since the first mounted component 30 is located above the first circuit wiring 20, a portion or the entirety of the mount region 10B overlaps a portion of the wiring region 10A. The region where the wiring region 10A and mount region 10B overlap will be referred to as overlap region 10C, which is shown in FIGS. 1(b) and 2. The overlap region 10C is in direct contact with the first circuit wiring 20 and is located between the first mounted component 30 and metal member 50 as determined in the direction perpendicular to the bottom surface 30b of the first mounted component 30 facing the substrate 70.

The surface roughness Rz of the overlap region 10C is to be 10 μm to 120 μm, preferably 15 to 150, or 20 μm to 100 μm. Further, the minimum distance t between the first circuit wiring 20 and the face 10b of the first resin layer 10 facing the metal member 50 as measured within the overlap region 10C is to be 10 μm to 100 μm, and preferably 30 μm to 100 μm, or 30 to 60 μm. The overlap region 10C is located directly below the electrical joint between the first mounted component 30, which is a heat source, and first circuit wiring 20 and thus can easily reach high temperatures during operation of the circuit part 100. In view of this, it is preferable to provide a construction that allows heat to escape easily from the overlap region 10C toward the metal member 50. Heat emitted by the first mounted component can be dissipated efficiently to the metal member 50 if the surface roughness Rz of the overlap region 10C is not lower than the lower limit of such a range as set forth above and the minimum distance tis not larger than the upper limit of such a range as set forth above. As a result, the heat dissipation of the entire circuit part 100 will be improved. On the other hand, the first circuit wiring 20 can be sufficiently insulated from the metal member 50 if the surface roughness Rz of the overlap region 10C is not higher than the upper limit of such a range as set forth above and the minimum distance tis not smaller than the lower limit of such a range as set forth above.

The surface roughness Rz of the overlap region 10C is a so-called “maximum height”, and is the distance between the highest and lowest locations of the overlap region 10C. The minimum distance tis the minimum distance from the deepest location of the overlap region 10C to the face 10b of the first resin layer 10. The surface roughness Rz of the overlap region 10C and the minimum distance t may be determined by, for example, SEM cross-section observation of the first resin layer 10 inclusive of the overlap region 10C. Similarly, the surface roughness Rz of portions of the wiring region 10A other than the overlap region 10C, as well as the surface roughness Rz of wiring-free region 10D, discussed further below, may be determined by SEM cross-section observation of the first resin layer 10.

The surface roughness Rz of portions of the wiring region 10A other than the overlap region 10C (hereinafter referred to as “region (10A-10C)” as appropriate) may be lower than the surface roughness Rz of the overlap region 10C. For example, the ratio of the surface roughness Rz of the region (10A-10C) to the surface region Rz of the overlap region 10C is preferably not higher than 1/2, not higher than 1/5, or not higher than 1/10. Since the first mounted component 30 is not present directly above, the region (10A-10C) is not required as much to have a construction that corresponds to the importance of heat dissipation as the overlap region 10C is. If the above-defined ratio of the surface roughnesses is within such a range as set forth above, the region (10A-10C) need not be significantly roughened, which means reduced processing (roughening) time, which improves the production efficiency of the entire circuit part 100. The surface roughness Rz of the region (10A-10C) may be, for example, 0.5 to 20 μm, 1 to 30 μm, or 10 to 40 μm.

Each of the overlap region 10C and the region (10A-10C) has a surface roughness Ra. A surface roughness Ra is an arithmetical mean roughness. A surface roughness Ra may be determined based on an SEM cross-section observation of the first resin layer 10. For example, the surface roughness Ra of the region (10A-10C) may be lower than the surface roughness Ra of the overlap region 10C. In other words, the surface roughness Ra of the overlap region 10C may be higher than the surface roughness Ra of the region (10A-10C). For example, the ratio of the surface roughness Ra of the region (10A-10C) to the surface roughness Ra of the overlap region 10C is preferably not higher than 0.9, not higher than 0.6, or not higher than 0.5. Since the first mounted component 30 is not present directly above, the region (10A-10C) is not required as much to have a construction that corresponds to the importance of heat dissipation as the overlap region 10C is. If the above-defined ratio of the surface roughnesses Ra is within such a range as set forth above, the region (10A-10C) need not be significantly roughened, which means reduced processing (roughening) time, which improves the production efficiency of the entire circuit part 100. The surface roughness Ra of the region (10A-10C) may be, for example, 0.3 to 20 μm, 0.5 to 1.5 μm, or 1 to 10 μm.

In FIG. 2, a region of the surface 10a of the first resin layer 10 where the first circuit wiring 20 is not present is indicated as a wiring-free region 10D. To improve adhesion to the first circuit wiring 20, the surface roughness Rz of the wiring region 10A is preferably higher than the surface roughness Rz of the wiring-free region 10D, and the surface roughness Ra of the wiring region 10A is preferably higher than the surface roughness Ra of the wiring-free region 10D. Furthermore, the surface roughness Rz of the overlap region 10C may be not lower than twice the surface roughness Rz of the wiring-free region 10D, and the surface roughness Ra of the overlap region 10C may be not lower than twice the surface roughness Ra of the wiring-free region 10D. Thus, directly below the first mounted component 30, which is a heat source, the plating film of the first circuit wiring 20 comes closer to the metal member 50, which serves as a heat-dissipating member, thereby further increasing heat dissipation.

The first resin layer 10 is not limited to any particular thickness 10d. In designing the first resin layer 10, its thickness 10d may be any suitable value, depending on the application of the circuit part 100, for achieving a surface roughness Rz of the overlap region 10C and a minimum distance t within such ranges as set forth above. The thickness 10d of the first resin layer 10 is preferably 10 μm to 200 μm, for example, and more preferably 40 μm to 100 μm. If the thickness 10d of the first resin layer 10 is smaller than the lower limit of such a range as set forth above, insulating properties may not be ensured; if the thickness is larger than the upper limit of such a range, this may lead to decreased heat dissipation and/or increased costs. The thickness of the first resin layer 10 can be reduced if the layer is applied to the metal member 50 than if it is shaped thereon. If the first resin layer 10 is formed by application, the first resin layer 10 has a relatively small thickness, ranging from 20 μm to 150 μm. The thickness of the first resin layer 10 formed by application is to be not smaller than 20 μm, preferably not smaller than 25 μm, and more preferably not smaller than 30 μm; it is to be not larger than 150 μm, preferably not larger than 100 μm, and more preferably not larger than 70 μm. In such implementations, the surface roughness Rz is to be not less than 10 μm, preferably not less than 15 μm, and more preferably not less than 20 μm; it is to be not more than 100 μm, preferably not more than 70 μm, and yet more preferably not more than 50 μm. As used herein, the thickness 10d of the first resin layer 10 is the thickness of portions of the layer where the first circuit wiring 20 is not present (including the wiring-free region 10D). The thickness 10d may be, for example, the distance from the surface 10a of the first resin layer 10 (e.g., wiring-free region 10D) to the face 10b of the first resin layer 10 facing the metal member 50.

The first circuit wiring 20 is formed from plating film on the wiring region 10A of the surface 10a of the first resin layer 10. The first circuit wiring 20 contains electroless-plating film formed on top of the wiring region 10A. It may further contain electroplating film formed on top of the electroless-plating film.

The electroless-plating film may be, for example, electroless nickel-phosphorus plating film, electroless copper plating film, or electroless nickel plating film, where electroless nickel-phosphorus plating film is particularly preferable. The electroplating film may be nickel-phosphorus electroplating film, copper electroplating film, or nickel electroplating film. Further, to improve the wettability of the plating film with respect to solder, plating film of gold, silver or tin, for example, may be formed as the outermost surface of the first circuit wiring 20.

The thickness of the first circuit wiring 20 is not limited to any particular value, and, in designing, may be any suitable value depending on the application of the circuit part 100. The thickness of the first circuit wiring 20 may be, for example, 10 to 100 μm, or 20 to 80 μm. As used herein, the thickness of the first circuit wiring 20 means the thickness of portions of the wiring located on the region (10A-10C).

As shown in FIG. 2, the first mounted component 30 is positioned such that a face thereof provided with a terminal (i.e., bottom surface) 30b faces the first circuit wiring 20, where the terminal is electrically connected to the first circuit wiring 20 by means of the solder 40. The first mounted component 30 is electrically connected to the first circuit wiring 20 via the solder 40 above the overlap region 10C. The solder 40 is not limited to any particular one, and may be a general-purpose solder. The first mounted component 30, when passing electric current, generates heat and becomes a heat source. The first mounted component 30 used may be any mountable component, and may be a light-emitting diode (LED), a power module, an integrated circuit (IC), or a thermal resistor, for example.

The circuit part 100 according to the present embodiment may be provided with another functional layer different from the first resin layer 10 (not shown), e.g., a radiation layer, on portions of the surface of the metal member 50 where the first resin layer 10 is not present. The radiation layer has a higher emissivity than the first resin layer 10. The presence of the radiation layer will allow the circuit part 100 according to the present embodiment to dissipate heat generated by the first mounted component 30 even more efficiently. The radiation layer may only be present on some portions of the surface of the metal member 50, or may cover all the portions of the surface of the metal member 50 where the first resin layer 10 is not present. The radiation layer may be, for example, anodized aluminum or electrodeposition coating film. Furthermore, if the first circuit wiring 20 is formed using electroless plating, the radiation layer prevents precipitation of electroless-plating film on the surface of the metal member 50.

In the circuit part 100 according to the present embodiment described above, the surface roughness Rz of the overlap region 10C of the surface 10a of the first resin layer 10 is within a specified range. Further, the minimum distance t between the first circuit wiring and the face 10b of the first resin layer 10 facing the metal member 50 in the overlap region 10C is within a specified range. This will improve the heat dissipation of the entire circuit part 100 and, at the same time, sufficiently insulate the first circuit wiring 20 from the metal member 50.

### <Method of Manufacturing Circuit Part>

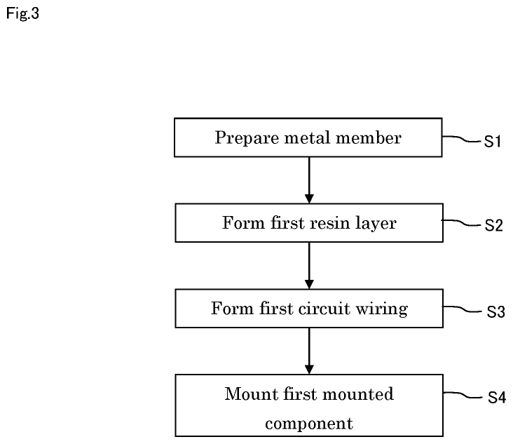

A method of manufacturing the circuit part 100 will be described with reference to the flow chart shown in FIG. 3.

### (1) Preparation of Metal Member 50

First, a metal member 50 is prepared (step S1 in FIG. 3). The metal member 50 may be a commercially available product, such as radiating fins, or may be provided through cutting into a desired shape, or formed by die casting. The surface of the metal member 50 on which the first resin layer 10 is to be formed may be roughened to increase its adhesion to the first resin layer 10 to be deposited thereon. The surface of the metal member 50 may be roughened using a known method, such as chemical etching, blasting, or laser roughening.

### (2) Formation of First Resin Layer 10

Next, a first resin layer 10 is formed on top of the metal member 50 (step S2 in FIG. 3). The formation of the first resin layer 10 is not limited to any particular method. For example, the first resin layer 10 may be formed by insert molding, for example, using injection molding or transfer molding (i.e., integral molding).

Alternatively, the first resin layer 10 may be formed by shaping a resin sheet (i.e., first resin sheet) having generally the same composition as the first resin layer 10 on top of the metal member 50. For example, the metal member 50 may be used as a lower half of a die, and a resin sheet may be sandwiched between the lower half of the die (i.e., metal member 50) and the upper half of the die, and pressed. The resin sheet is thus shaped, where a first resin layer 10 with a uniform, small thickness can be easily formed, in a short period of time, on the three-dimensional surface of the lower half of the die (i.e., metal member 50). Furthermore, an upper half of the die is not necessarily required to shape a resin sheet. For example, with pressure forming or vacuum forming, a first resin layer 10 may be formed by shaping a first resin sheet on top of the lower half of the die (i.e., metal member 50) without using an upper half of the die. This will reduce the cost and time required to fabricate the die.

Alternatively, the first resin layer 10 may be formed by applying a resin liquid (i.e., first resin liquid) to the metal member 50. Applying the first resin liquid allows easy formation, in a short period of time, of a first resin layer 10 with a uniform and small thickness on the three-dimensional surface of the metal member 50.

The application of the first resin liquid to the metal member 50 is not limited to any particular method. For example, a spray coater may be used. Further, after application of the first resin liquid, the metal member 50 with the coating formed thereon is preferably heated. The heating temperature and heating time can be adjusted as appropriate depending on the composition of the first resin liquid, for example.

The composition of the first resin liquid may be adjusted as appropriate such that a first resin layer 10 with a desired composition can be formed. For example, if the first resin layer 10 contains a thermosetting resin such as an epoxy resin, the first resin liquid may be an epoxy paint. In such implementations, the first resin liquid is applied to the metal member 50 and, thereafter, the coating is heated to cure the thermosetting resin to form the first resin layer 10. In addition, to regulate the viscosity of the first resin liquid to improve the workability of application, the first resin liquid may contain a solvent in addition to the ingredients constituting the first resin layer 10. The solvent, after application, volatilizes from the coating, and thus is not contained in the resulting first resin layer 10. The type and amount of the solvent may be selected as appropriate depending on the type of the resin contained in the first resin liquid, for example.

As will be described further below, the wiring region 10A is roughened to allow the first circuit wiring 20 to be formed thereon, and the thickness of portions of the first resin layer 10 located in the wiring region 10A prior to roughening is preferably 10 to 200 μm, and more preferably 40 to 100 μm. If the thickness is smaller than the lower limit of such a range, insulating properties may not be ensured; if the thickness is larger than the upper limit of such a range, this may lead to decreased heat dissipation and/or increased costs. Further, to stabilize heat dissipation and insulating properties, the thickness of portions of the layer located in the wiring region 10A prior to roughening is preferably within the range of the average film thickness±30%, and more preferably within the range of the average film thickness±10%.

### (3) Formation of First Circuit Wiring 20

Next, first circuit wiring 20 containing plating film is formed on the wiring region 10A of the first resin layer 10 (step S3 in FIG. 3). The formation of the first circuit wiring 20 is not limited to any particular method, and a common method may be used. For example, one method involves forming plating film on the entire surface 10a and providing a photoresist pattern on the plating film, before removing the portions of the plating film other than the circuit wiring through etching; another method involves illuminating, with a laser beam, the portions of the resin layer on which circuit wiring is to be formed to roughen those portions, and forming plating film on only those portions that have been illuminated with a laser beam. Particularly, in implementations where the first resin layer 10 is made of a thermosetting resin such as an epoxy resin, the wiring region 10A may be roughened with a laser beam to promote adsorption of metal ions that are to serve as a plating catalyst, thereby making it easier to form electroless-plating film only within the wiring region 10A.

According to the present embodiment, for example, the following method, which is disclosed in WO 2018/131492 A1, is used to form the first circuit wiring 20: First, a catalytic-activity inhibitor layer is formed on the surface 10a of the first resin layer 10. Next, the wiring region 10A of the surface 10a, provided with the catalytic-activity inhibitor layer, is illuminated with a laser beam to remove the portions of the catalytic-activity inhibitor layer that are located in the wiring region 10A. Next, the wiring region 10A illuminated with a laser beam is provided with an electroless-plating catalyst, and an electroless-plating solution is brought into contact therewith. The catalytic-activity inhibitor layer prevents (i.e., inhibits) the catalytic activity of the electroless-plating catalyst provided thereon. This prevents production of electroless-plating film on the catalytic-activity inhibitor layer. On the other hand, within the wiring region 10A, the catalytic-activity inhibitor layer has been removed and thus electroless-plating film is produced. This forms first circuit wiring 20 formed from electroless-plating film in the wiring region 10A.

The catalytic-activity inhibitor layer contains a catalytic-activity inhibitor agent (i.e., catalyst inactivator) that prevents (i.e., inhibits), the catalytic activity of an electroless-plating catalyst. The catalytic-activity inhibitor agent (i.e., catalyst inactivator) is not limited to any particular one; for example, dendritic polymers such as dendrimers and hyperbranched polymers disclosed in WO 2018/131492 A1 are preferable. They have good catalyst inactivation capabilities and, because they are polymers, they can form a catalytic-activity inhibitor layer without the use of a binder resin. The electroless plating catalyst is not limited to any particular one, and a general-purpose catalyst may be selected and used as appropriate; for example, a plating catalyst solution containing metal salts such as palladium chloride may be used.

Further, according to the present embodiment, the wiring region 10A may be roughened at the same time as the relevant portions of the catalytic-activity inhibitor layer are removed by illuminating the wiring region 10A with a laser beam. Specifically, the surface roughness Rz of the overlap region 10C and the surface roughness Rz of the region (10A-10C) may be adjusted to such specific ranges as set forth above through illumination with a laser beam. At the same time, the minimum distance t between the first circuit wiring and the face 10b of the first resin layer 10 facing the metal member 50 as measured within the overlap region 10C may be adjusted to such a range as set forth above. The surface roughness of the wiring region 10A can easily be regulated by changing laser-beam illumination conditions (i.e., laser drawing conditions) such as laser-beam intensity or laser-beam illumination pattern. The type of laser beam or laser processing device used for laser-beam illumination are not limited to any particular ones, and appropriate ones may be selected taking account of the type of the first resin layer 10, for example.

The first circuit wiring 20 may contain electroplating film together with the electroless-plating film, in which case electroplating film may be formed on top of the electroless-plating film. The formation of the electroplating film is not limited to any particular method, and a common electroplating method may be selected and used as appropriate.

According to the present embodiment, the first circuit wiring 20 is formed using a catalytic-activity inhibitor layer; alternatively, the first circuit wiring 20 may be formed without using a catalytic-activity inhibitor layer. Using a catalytic-activity inhibitor layer prevents plating reactions outside the wiring region 10A, thereby increasing the selectivity of plating film. However, the wiring region 10A, which has been roughened by laser-beam illumination, has increased plating reactivity compared with regions that have not been illuminated with a laser beam (i.e., wiring-free region 10D). Electroless-plating film may be selectively formed, i.e., only on the wiring region 10A with increased plating reactivity, without using a catalytic-activity inhibitor layer by adjusting the type (i.e., composition) of the first resin layer 10, the type and concentration of the electroless-plating solution, etc.

### (4) Mounting of First Mounted Component 30

After the first circuit wiring 20 has been formed on the first resin layer 10, a first mounted component 30 is mounted on top of the first circuit wiring 20 (step S4 in FIG. 3). This results in the circuit part 100 according to the present embodiment. The mounting of the first mounted component 30 is not limited to any particular method, and a common method may be used. For example, the first mounted component 30 may be soldered to the first resin layer 10 by the solder-reflow method, in which solder at room temperature and the first mounted component 30 are placed on top of the first circuit wiring 20 and then the part is passed through a high-temperature reflow furnace, or by the laser-soldering method (i.e., spot mounting), in which a laser beam is directed to the interface between the first resin layer 10 and first mounted component 30 for soldering.

In the above-described method of manufacturing the circuit part 100, the first resin layer 10 may be formed by shaping a first resin sheet on top of the metal member 50 or applying a first resin liquid thereto. This method enables easy formation, in a short period of time, of a first resin layer 10 with a uniform and small thickness on the three-dimensional surface of the metal member 50, thereby increasing the production efficiency of the circuit part 100. The ability to form a thin first resin layer 10 makes it easier to provide both heat dissipation and insulating properties to the circuit part 100. Further, the ability to form a thin first resin layer 10 reduces the laser drawing time for the overlap region 10C until the minimum distance t falls within a specified range, for example. This will further increase the production efficiency of the circuit part 100.

### Second Embodiment

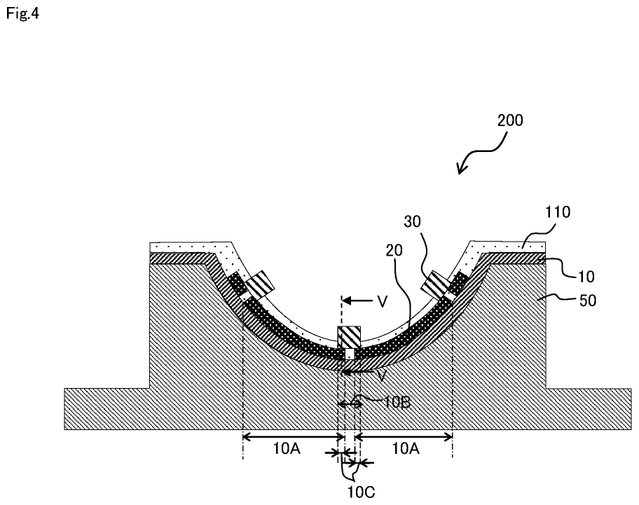

A circuit part 200 according to the present embodiment shown in FIGS. 4 and 5 will be described. The circuit part 200 includes a second resin layer 110. The second resin layer 110 is present on portions of the surface 10a of the first resin layer 10 other than the overlap region 10C to cover the first circuit wiring 20. The construction of the circuit part 200 is the same as that of the circuit part 100 according to the first embodiment except that the part 200 includes the second resin layer 110, and the common elements will not be described.

The second resin layer 110 may have the same construction as the first resin layer 10 of the circuit part 100 described in connection with the first embodiment. The thickness of the second resin layer 110 is preferably larger than the thickness of the first circuit wiring 20 such that it is able to cover the first circuit wiring 20. In the circuit part 200 according to the present embodiment, the resin contained in the first resin layer 10 and the resin contained in the second resin layer 110 may be the same or different. To improve adhesive properties between the first and second resin layers 10 and 110, the first and second resin layers 10 and 110 preferably contain the same resin.

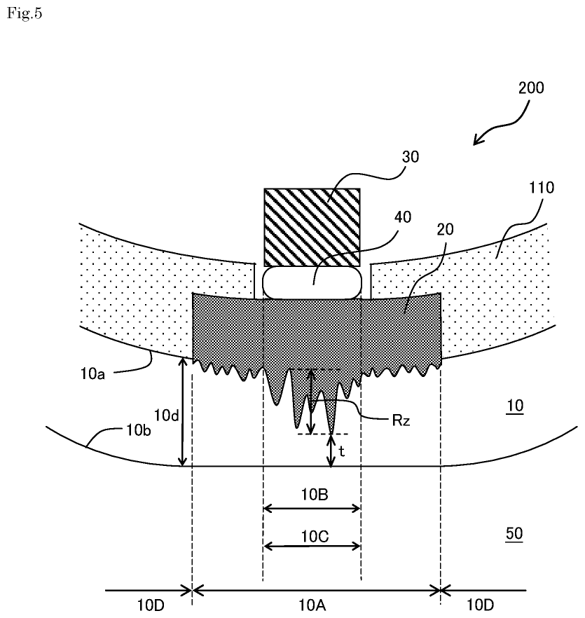

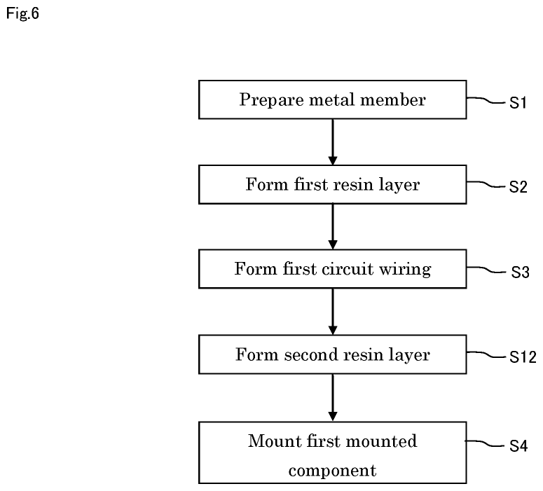

A method of manufacturing the circuit part 200 shown in FIG. 6 will be described. First, similarly to the method of manufacturing the circuit part 100 described in connection with the first embodiment, a metal member 50 is prepared (step S1 in FIG. 6), a first resin layer 10 is formed on top of the metal member 50 (step S2 in FIG. 6), and first circuit wiring 20 is formed on top of the first resin layer 10 (step S3 in FIG. 6).

Next, a second resin layer 110 is formed on portions of the surface 10a of the first resin layer 10 other than the overlap region 10C to cover the first circuit wiring 20 (step S12 in FIG. 6). The formation of the second resin layer 110 is not limited to any particular method, and may be performed through shaping of a resin sheet (i.e., second resin sheet) or application of a resin liquid (i.e., second resin liquid), described in connection with the method of forming the first resin layer 10 according to the first embodiment, for example. Applying of a second resin liquid is particularly preferable since it allows a second resin layer to be easily formed on the surface 10a, which is not flat anymore due to the formation of the first circuit wiring. Further, the second resin layer 110 may first be formed over the entire surface 10a inclusive of the overlap region 10C before removing the portions of the second resin layer 110 present above the overlap region 10C through laser-beam illumination, for example.

After formation of the second resin layer 110, a first mounted component 30 is mounted on the mount region 10B of the first resin layer 10 (step S4 in FIG. 6). The mounting of the first mounted component 30 may be performed by the same method as for the first embodiment. The second resin layer 110 is not present above the overlap region 10C. In other words, the portions of the first circuit wiring 20 located above the overlap region 10C are not covered with the second resin layer 110 and are exposed. The first mounted component 30, above the overlap region 10C, is electrically connected to the first circuit wiring 20, which is exposed i.e. not covered with the second resin layer 110, via the solder 40.

Typically, the higher the surface roughness of a resin layer on which circuit wiring (i.e., plating film) is formed, the higher the adhesive strength of this circuit wiring; the lower the surface roughness of the layer, the lower the adhesive strength of the wiring. However, in the circuit part 200 according to the second embodiment, the second resin layer 110 covers and protects the first circuit wiring 20 provided on top of the region (10A-10C). Thus, even if the surface roughness of the region (10A-10C) is reduced, the first circuit wiring 20 provided on top of the region (10A-10C) does not easily peel off, which improves the reliability of the circuit part 200. If the surface roughness of the region (10A-10C) is low, this reduces the processing (i.e., roughening) time, thereby improving the production efficiency of the entire circuit part 100. The present embodiment improves the reliability and production efficiency of the circuit part 200 at the same time. The surface roughness Rz of the region (10A-10C) may be lower than the surface roughness Rz of the overlap region 10C; for example, the ratio of the surface roughness Rz of the region (10A-10C) to the surface roughness Rz of the overlap region 10C is preferably not higher than 1/2, not higher than 1/5, or not higher than 1/10. The surface roughness Rz of the region (10A-10C) may be, for example, 0.5 to 20 μm, 1 to 30 μm or 10 to 40 μm. Furthermore, the ratio of the surface roughness Ra of the region (10A-10C) to the surface roughness Ra of the overlap region 10C is preferably not higher than 0.9, not higher than 0.6 or not higher than 0.5. The surface roughness Ra of the region (10A-10C) may be, for example, 0.3 to 20 μm, 0.5 to 15 μm or 1 to 10 μm.

It is to be noted that the second resin layer 110 need not cover all the portions of the surface 10a other than the overlap region 10C. For example, as shown in FIG. 5, some portions of the wiring region 10A around the overlap region 10C may be not covered with the second resin layer 110 to make it easier to mount the first mounted component 30. In other words, the second resin layer 110 need not cover the entire first circuit wiring 20. Further, the second resin layer 110 may also be present on the wiring-free region 10D, as shown in FIG. 5. On the contrary, the resin layer 110 may not be present on the wiring-free region 10D.

### Third Embodiment

A circuit part 300 according to the present embodiment shown in FIG. 7 will be described. The circuit part 300 includes a second resin layer 110, second circuit wiring 120 containing plating film formed on top of the second resin layer 110, and a second mounted component 130 mounted on top of the second circuit wiring 120 to electrically connect to the second circuit wiring 120. The second resin layer 110 is present on portions of the surface 10a of the first resin layer 10 other than the overlap region 10C to cover the first circuit wiring 20. The construction of the circuit part 300 is generally the same as that of the circuit part 100 according to the first embodiment except for the second resin layer 110, second circuit wiring 120 and second mounted component 130, and the common elements will not be described.

The second resin layer 110 may have the same construction as the second resin layer 110 described in connection with the second embodiment. Further, the second circuit wiring 120 and second mounted component 130 may have the same construction as the first circuit wiring 20 and first mounted component 30 of the circuit part 100 described in connection with the first embodiment. The first mounted component 30, above the overlap region 10C, is electrically connected to the first circuit wiring 20, which is exposed i.e. not covered with the second resin layer 110, via the solder 40. The second mounted component 130 is positioned such that a face thereof provided with a terminal (i.e., bottom surface) faces the second circuit wiring 120, and the terminal and the second circuit wiring 120 are electrically connected by the solder.

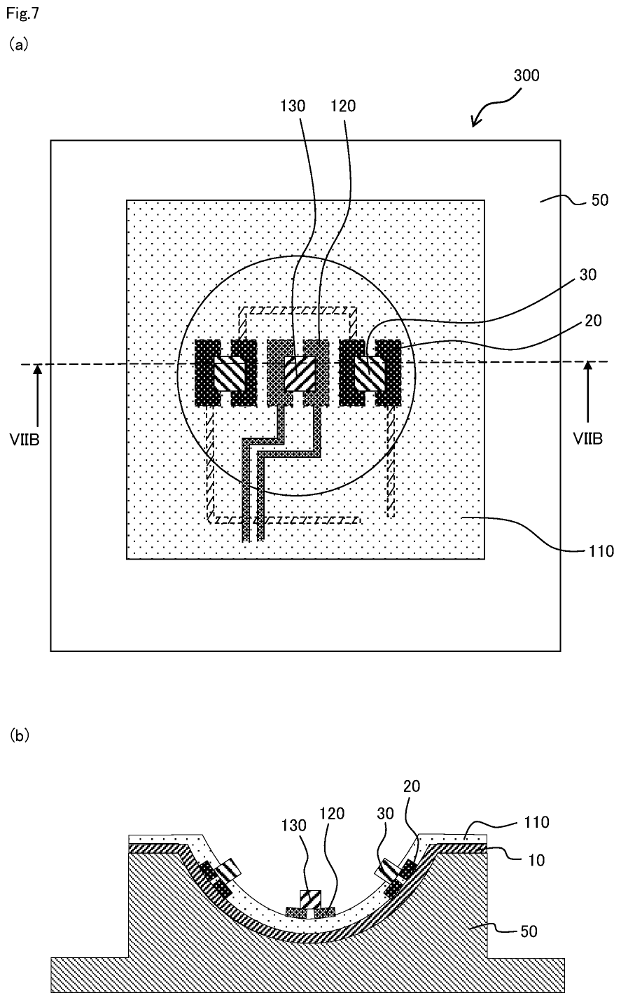

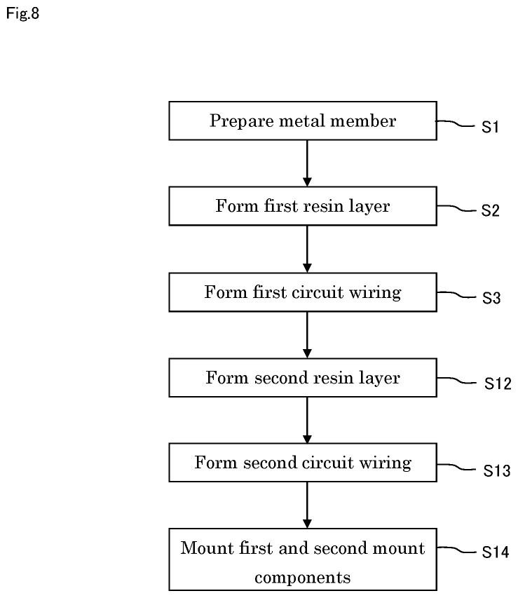

A method of manufacturing the circuit part 300 shown in FIG. 8 will be described. First, similarly to the method of manufacturing the circuit part 100 described in connection with the first embodiment, a metal member 50 is prepared (step S1 in FIG. 8), a first resin layer 10 is formed on top of the metal member 50 (step S2 in FIG. 8), and first circuit wiring 20 is formed on top of the first resin layer 10 (step S3 in FIG. 8). Next, a second resin layer 110 is formed on portions of the surface 10a of the first resin layer 10 other than the overlap region 10C (step S12 in FIG. 8). The second resin layer 110 may be formed by the formation method described in connection with the second embodiment. Next, second circuit wiring 120 is formed on top of the second resin layer 110 (step S13 in FIG. 8) and, thereafter, a first mounted component 30 and a second mounted component 130 are mounted (step S14 in FIG. 8). The second circuit wiring 120 may be formed by the same method as the method of forming the first circuit wiring 20 described in connection with the first embodiment. The first and second mounted components 30 and 130 may be mounted by the same method as the method of mounting the first mounted component 30 described in connection with the first embodiment.

The circuit part 300 according to the present embodiment is a three-dimensional circuit part, and has a laminated structure in which the second circuit wiring 120 provided on the second resin layer 110 lies higher than the first circuit wiring 20 provided on the first resin layer 10. Thus, the circuit part 300 enables formation of a high-density circuit. Higher circuit density requires the circuit part to have higher heat dissipation. The circuit part 300 provides sufficient heat dissipation as the surface roughness Rz of the overlap region 10C is within a specified range and the minimum distance tis within a specified range. To further increase heat dissipation, it is preferable that a mounted component with a larger amount of heat emission is mounted on top of the first resin layer 10, which is close to the metal member 50. In other words, the first mounted component 30 may be a component with a larger amount of heat emission than the second mounted component 130. Further, according to the present embodiment, the second resin layer 110 may be formed by applying a second resin liquid. This method allows a second resin layer to be easily formed on the surface 10a, which is a three-dimensional surface and is not flat anymore due to the formation of the first circuit wiring, and thus makes it easier to provide a multi-layer circuit in a three-dimensional circuit part. Although the circuit part 300 has two resin layers each provided with circuit wiring stacked on top of each other, the present embodiment is not limited to such an implementation. The circuit part according to the present embodiment may have three or more resin layers each provided with circuit wiring stacked on top of one another.

### Fourth Embodiment

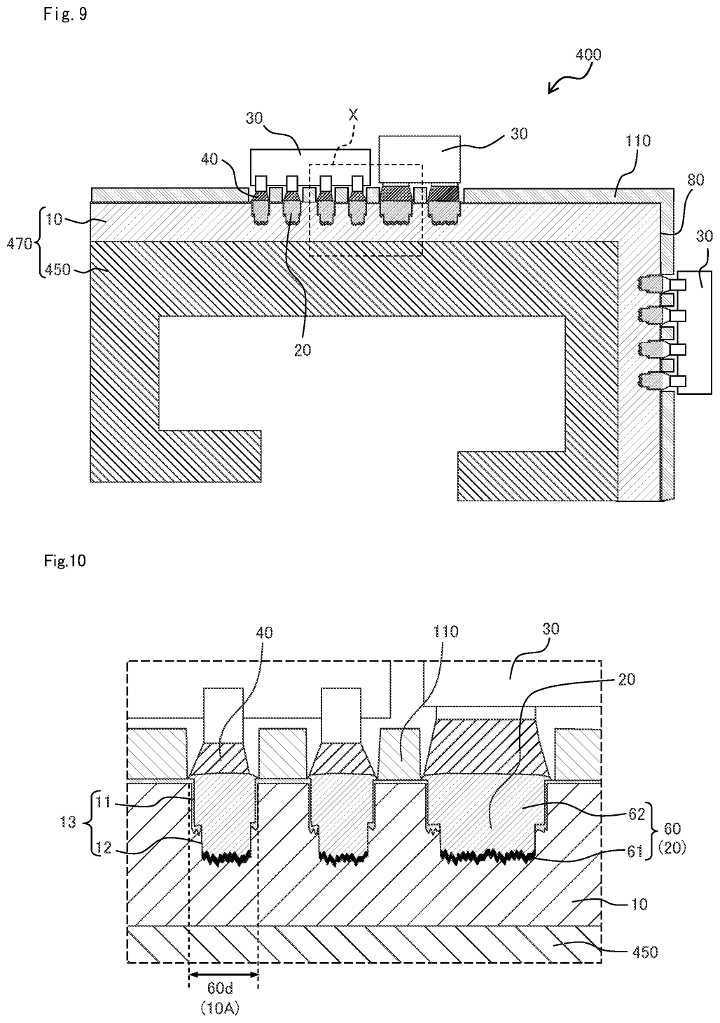

A circuit part 400 according to the present embodiment shown in FIGS. 9 and 10 will be described. The basic construction of the circuit part 400 is generally the same as that of the circuit part 200 according to the second embodiment (see FIG. 4). However, the circuit part 400 is different from the circuit part 200 according to the second embodiment in that, among others, the metal member 450 is a product of sheet metal working and a two-stage groove structure 13 composed of a first groove 11 and a second groove 12 is formed in the wiring region 10A of the first resin layer 10. The construction of the circuit part 400 will now be described together with a method of manufacturing it.

### <Method of Manufacturing Circuit Part 400>

The method of manufacturing the circuit part 400 will be described with reference to the flow chart shown in FIG. 6.

### (1) Sheet Metal Working for Metal Member 450

First, a metal member 450 is produced through sheet metal working (step S1 in FIG. 6). Sheet metal working involves processing a thin metal sheet and thus allows a light-weight member to be produced more easily than cutting, casting or forging, and also requires a shorter processing time. Further, it does not require a dedicated die to be made, thus enabling low-cost, small-lot production.

According to the present embodiment, as shown in FIG. 9, a thin metal sheet is subjected to sheet metal working to produce a hollow, sheet-shaped metal member 450 having an opening at the bottom. As the thin metal sheet is bent, its strength is increased; further, as the member is hollow, its heat dissipation is improved.

The metal member 450 may be made of a known metal listed in connection with the first embodiment, where copper, aluminum and stainless steel (SUS) are preferable to provide high thermal conduction, workability and reliability. One of these metals may be used alone, or a mixture of two or more may be used, or an alloy may be used. The portions of the surface of the metal member 450 where a first resin layer 10 is to be present are preferably roughened to improve adhesion to the first resin layer 10 to be placed thereon.

### (2) Formation of First Resin Layer 10

Next, a first resin layer 10 is formed on top of the metal member 450 through application (step S2 in FIG. 6). The first resin layer 10 may be made of a resin listed in connection with the first embodiment, where thermosetting or photocurable epoxy resins are particularly preferable. Further, to improve applicability and thermal conductivity, the first resin layer 10 preferably contains insulating, spherical thermal conductive filler with a particle diameter of 0.1 to 30 μm, preferably 1 to 10 μm.

The first resin layer 10 may be formed by the application method described in connection with the first embodiment. For example, a resin liquid (i.e., first resin liquid) may be applied to the metal member 450 by spraying to form a coating, which is then cured by heating or ultraviolet irradiation to form the first resin layer 10.

### (3) Formation of First Circuit Wiring 20

Next, first circuit wiring 20 containing plating film 60 is formed on the wiring region 10A of the first resin layer 10 by the following method (step S3 in FIG. 6).

### (3-1) Formation of First Groove 11

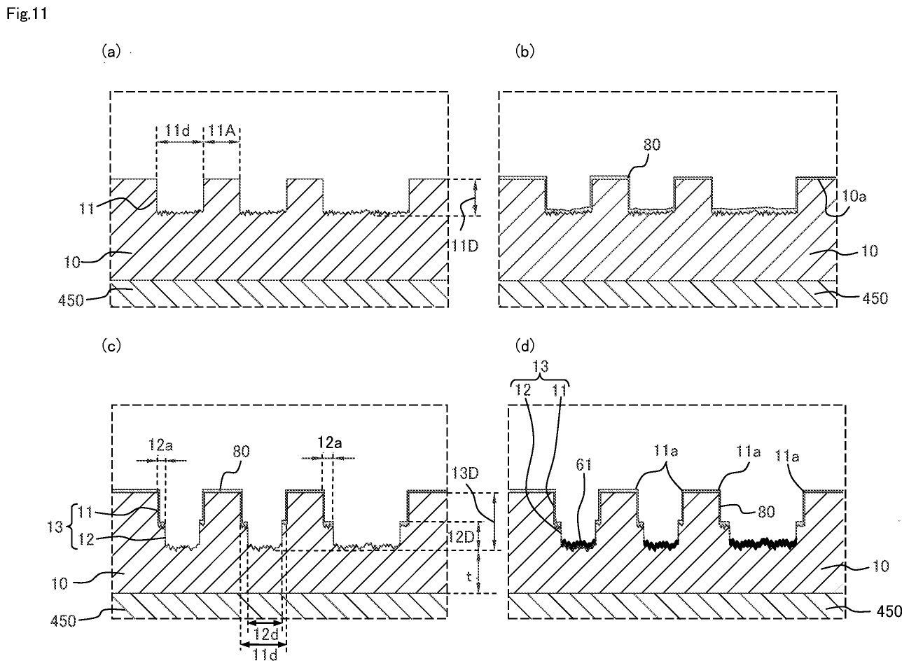

As shown in FIG. 11(a), a first groove 11 is formed in the wiring region 10A of the first resin layer 10. The first groove 11 extends in the directions in which the first circuit wiring 20 extends. The first groove 11 may be formed by press working using projections on the die, for example, or may be formed by laser-beam illumination (i.e., laser drawing or laser cutting). As will be discussed further below, the plating film 60 fills the two-stage groove structure 13 and may then further spread outward from the two-stage groove structure 13; in view of this, the width 11d of the first groove 11 is preferably smaller than the expected width 60d of the plating film 60 to be formed thereon (see FIG. 10). The width 60d of the plating film 60 is also the width of the wiring region 20A. Thus, the width 11d of the first groove 11 is preferably smaller than the width of the wiring region 20A. As used herein, the width 11d of the first groove 11, the width 60d of the plating film 60 (i.e., width of the wiring region 20A), and the width 12d of the second groove 12, discussed further below, each mean a width (or dimension) as measured in the direction along the surface 10a of the first resin layer 10 that is perpendicular to the direction in which the first circuit wiring 20 extends. Further, the direction along the surface 10a of the first resin layer 10 that is perpendicular to the direction in which the first circuit wiring 20 extends will sometimes be referred to as “line-width direction”.

### (3-2) Formation of Catalytic-Activity Inhibitor Layer 80 and Formation of Second Groove 12

As shown in FIG. 11(b), a catalytic-activity inhibitor layer 80 is formed on the surface 10a of the first resin layer 10, inclusive of the wiring region 10A, by the same method as for the first embodiment. After formation of the catalytic-activity inhibitor layer 80, as shown in FIG. 11(c), a second groove 12 is formed inside the first groove 21 by laser-beam illumination (i.e., laser drawing or laser cutting). This results in a two-stage groove structure 13 composed of the first and second grooves 11 and 12. The width 12d of the second groove 12 is smaller than the width 11dof the first groove 11. Similar to the first groove 11, the second groove 12 extends in the direction in which the first circuit wiring 20 extends. The catalytic-activity inhibitor layer 80 is also removed by the laser-beam illumination (i.e., laser cutting). Thus, as shown in FIG. 11(c), the catalytic-activity inhibitor layer 80 is not present inside the second groove 12, while the catalytic-activity inhibitor layer 80 is present in the other regions.

### (3-3) Electroless Plating and Electroplating

Next, an electroless-plating catalyst is applied to the wiring region 10A and an electroless-plating solution is brought into contact therewith. As discussed above, the catalytic-activity inhibitor layer 80 is not present inside the second groove 12 while the catalytic-activity inhibitor layer 80 is present in the other regions. Thus, production of plating film is prevented on the sides of the first groove 11 while plating activity is increased inside the second groove 12. Plating catalyst can easily be accumulated on the bottom of the second groove 12 such that plating film is formed there particularly easily. As a result, as shown in FIG. 11(d), the electroless-plating film (i.e., foundation plating film) 61 is mainly formed on the bottom of the second groove 12.

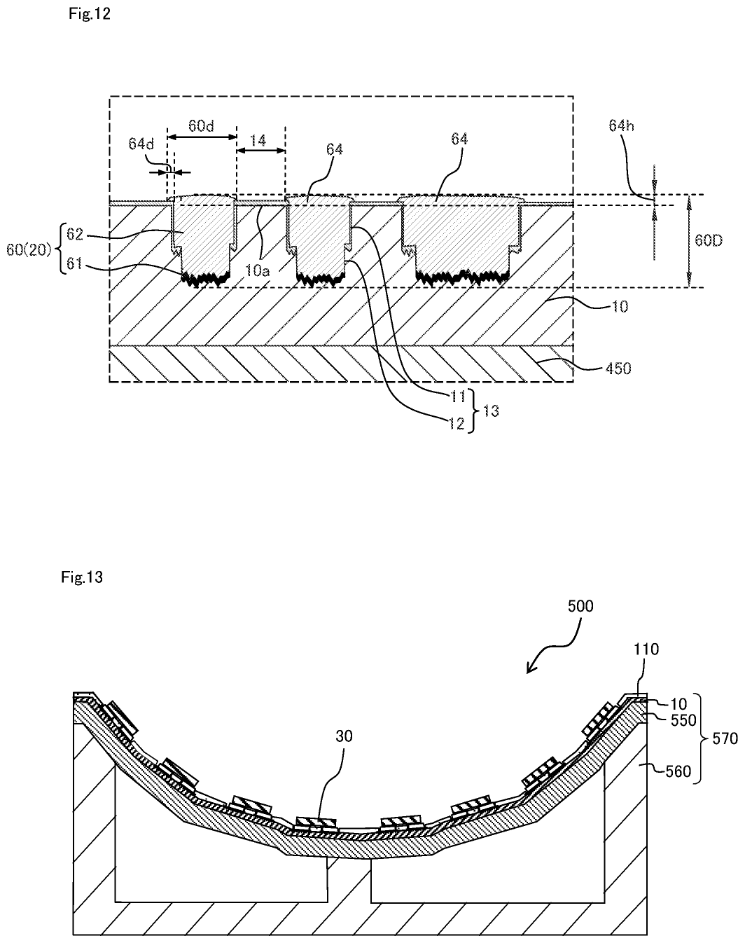

After formation of the electroless-plating film (i.e., foundation plating film) 61 on the bottom of the second groove 12, electroplating is performed. Electric conduction is ensured at the bottom of the second groove 12 due to the electroless-plating film 61 such that electroless-plating film 61 can easily grow. On the other hand, electric conduction is insufficient at the sides of the first groove 11 such that growth of electroplating film is prevented on the sides of the first groove 11. As a result, as shown in FIG. 12, the electroplating film 62 grows from the bottom of the second groove 12 in a “bottom-up” manner to fill the two-stage groove structure 13, thus forming first circuit wiring 20.

### (4) Formation of Second Resin Layer 110 and Mounting of First Mounted Component 30

After formation of the first circuit wiring 20, a second resin layer 110 is formed by the same method as for the second embodiment, and a first mounted component 30 is mounted, resulting in the circuit part 400 (steps S12 and S4 in FIG. 6).

### <Construction of Circuit Part 400>

The circuit part 400 according to the present embodiment has generally the same construction as the circuit part 200 according to the second embodiment (see FIG. 4). Thus, it produces the same effects produced by the circuit part 200. In addition, according to the present embodiment, the metal part 450 is formed by sheet metal working, which reduces manufacturing costs and also increases production efficiency.

Further, in the circuit part 400, the two-stage groove structure 13 including the first and second grooves 11 and 12 is formed in the wiring region 10A of the first resin layer 10. In the circuit part 400, the presence of the two-stage groove structure 13 enables reducing the line width of the first circuit wiring 20 (i.e., width 60d of the plating film 60), which ensures that the lines of the wiring are insulated from one another even in implementations where the thickness of the plating film 60 must be increased. The mechanism for this will be described below.

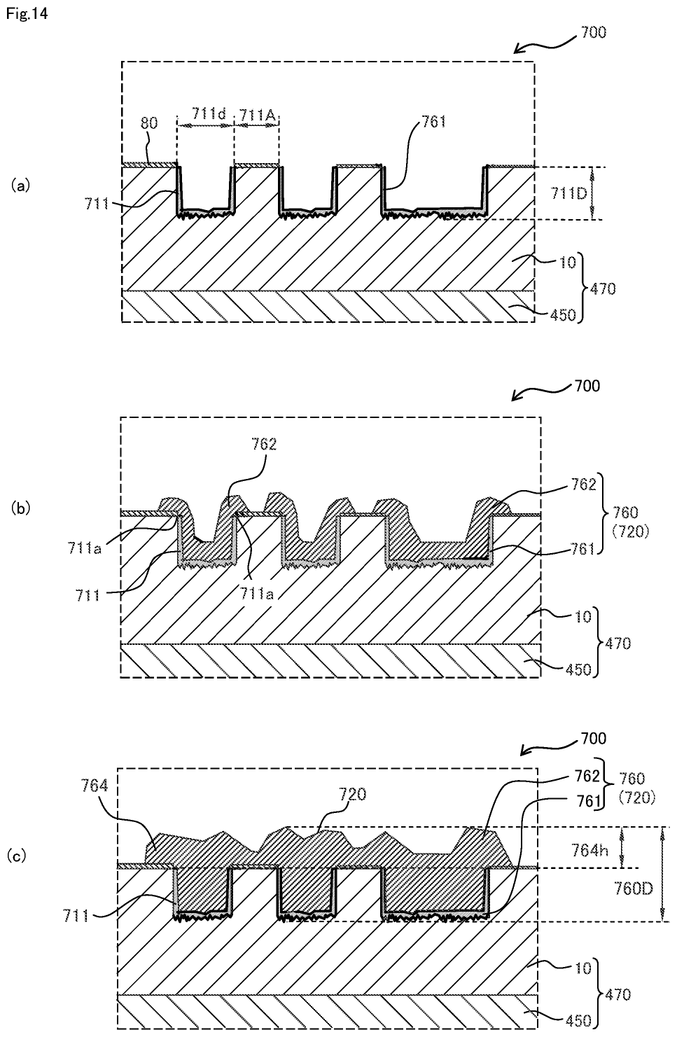

During electroplating, larger amounts of electric current flow at corners and/or protrusions of the surface on which plating film is to be formed such that thick electroplating film can easily be formed at these locations, causing unevenness in film thickness. For example, as shown in FIG. 14(b), when wiring 720 with electroplating film 762 contained inside the groove 711 is to be formed, thick electroplating film 762 is formed at the edges 711a (i.e., corners) of the opening of a groove 711. Then, before the interior of the groove 711 is filled with the electroplating film 762, the electroplating film 762 grows to spread outward of the groove 711. As a result, adjacent lines of the wiring 720 are joined together, making it impossible to ensure insulation of the lines from each other (see FIG. 14(c)). This problem becomes more significant as the line width of the wiring 720 decreases or the film thickness of the electroplating film 762 increases (i.e., the depth of the groove 711 increases).

In contrast, according to the present embodiment, the presence of the two-stage groove structure 13 reduces the growth of plating film on the sides of the first groove 11 inclusive of the edges (i.e., corners) 11a of its opening (see FIG. 11(d)), causing the electroplating film 62 to grow from the bottom of the second groove 12 in a bottom-up manner. Thus, the electroplating film 62 fills the two-stage groove structure 13 and still does not spread excessively outward of the two-stage groove structure 13. This ensures that the lines of the first circuit wiring 20 are insulated from one another. It is to be understood that the groove formed in the wiring region 10A according to the present embodiment is not limited to a two-stage groove structure. For example, a multi-stage groove structure may be provided where yet another groove is formed within the second groove 12.

In implementations where the first mounted component 30 is a power device that needs to pass large current, the packaging density is high and the line width of the first circuit wiring 20 is small, which requires the film thickness of the plating film 60 to be increased. Even in such implementations, the circuit part 400 according to the present embodiment enables increasing the depth of the two-stage groove structure 13 and providing sufficient film thickness for the plating film 60 and still prevents the plating film 60 from excessively spreading outward from the two-stage groove structure 13, thereby ensuring that the lines of the first circuit wiring 20 are insulated from one another. Although there are conventional techniques that use protection film such as resist to prevent an increase of the circuit wiring width, the circuit part 400, without using such conventional techniques, provides both a reduction of the line width of the first circuit wiring 20 and an increase of the thickness of the plating film 60.

The plating film 60 of the first circuit wiring 20 fills the two-stage groove structure 13 and may further include a protrusion 64 protruding outward from the two-stage groove structure 13 (see FIG. 12). However, the height 64h of the protrusion 64 as measured from portions of the surface 10a of the first resin layer 10 where the first circuit wiring 20 is not present is preferably not larger than 30% of the film thickness 60D of the plating film 60 of the first circuit wiring 20, and more preferably not larger than 20%. Further, the height 64h is preferably not larger than 20 μm. If the height 64h of the protrusion 64 exceeds such a range, the plating film 60 spreads in the line-width directions to such an extent that it may become difficult to reduce the line width of the first circuit wiring 20.

As shown in FIG. 12, the protrusion 64 may spread in the line-width direction from the two-stage groove structure 13 along the surface 10a of the first resin layer 10. In such implementations, since the width of the protrusion 64 in the line-width direction is the line width of the first circuit wiring 20 (i.e., width 60d of the plating film 60), the line width of the first circuit wiring 20 is larger than the width of the two-stage groove structure 13 (i.e., width 11dof the first groove 11). However, the dimension 64d of the portion of the protrusion 64 that protrudes from the two-stage groove structure 13 in the line-width direction as measured along the surface 10a of the first resin layer 10 is preferably not larger than 30% of the line width 60d of the first circuit wiring. If the dimension 64d exceeds this range, it may be difficult to provide a small line width of the first circuit wiring 20.

The ratio of the film thickness 60D of the plating film 60 of the first circuit wiring 20 to the line width 60d of the first circuit wiring 20, (60D/60d), may be 0.3 to 4 (see FIG. 12). In other words, the film thickness 60D of the plating film 60 of the first circuit wiring 20 may be 0.3 to 4 times the line width 60d of the first circuit wiring 20. Further, the film thickness 60D of the plating film 60 of the first circuit wiring 20 may be 15 to 100 μm. If the ratio (60D/60d) is within such a range, the first circuit wiring 20 is considered to have a high aspect ratio with a sufficiently large film thickness 60D relative to the width 60d of the plating film. Wiring with high aspect ratio has small line width and thus enables increasing density, and has a large film thickness of plating film and thus is able to pass large current. According to the present embodiment, the thickness of portions of the plating film 60 that are located within the first resin layer 10 is increased and the thickness of portions exposed at the surface 10a of the first resin layer 10 (i.e., protrusions 64) is reduced, thereby preventing the plating film from spreading in the direction of the wiring while providing high aspect ratio.

### Fifth Embodiment

A circuit part 500 according to the present embodiment shown in FIG. 13 will be described. The circuit part 500 includes a substrate 570 including a metal member 550 constituted by a product of sheet metal working formed through sheet metal working, a reinforcement member 560 that reinforces the metal member 550, and a first resin layer 10. The construction of the circuit part 500 is the same as that of the circuit part 400 according to the fourth embodiment (see FIG. 9) except for the substrate 570 including the reinforcement member 560, and the common elements will not be described.

The metal member 550 is provided by processing a thin metal sheet through sheet metal working into a three-dimensional shape (i.e., polyhedron). It may be made of a known metal listed in connection with the fourth embodiment. Since the metal member 550 is constituted by a thin metal sheet, it alone may have insufficient rigidity. According to the present embodiment, a reinforcement member 560 is provided on the face of the metal member 550 opposite to the face provided with the first circuit wiring 20, thereby reinforcing the metal member 550. The reinforcement member 560 may be made of a metal or a resin. For example, both the metal member 550 and reinforcement member 560 may be formed from aluminum and be welded together.

The circuit part 500 according to the present embodiment has generally the same construction as the circuit part 400 according to the fourth embodiment (see FIG. 9), and produces the same effects produced by the circuit part 400. In addition, the circuit part 500 according to the present embodiment, by virtue of the presence of the reinforcement member 560, increases the dimensional accuracy of the metal member 550 constituted by a product of sheet metal working and, as a result, increases the reliability of the substrate 570.

Embodiments described above may be combined as long as they are not mutually exclusive.

### EXAMPLES

Now, the present invention will be specifically described with reference to inventive and comparative examples, although the present invention is not limited to these inventive and comparative examples.

### Inventive Example 1

For the present inventive example, a circuit part 100 as shown in FIG. 1 was fabricated. The first mounted component 30 was a light-emitting diode (LED).

### (1) Preparation of Metal Member

The material used for the metal member 50 was an aluminum alloy. A metal member 50 with a recess with a hemispherical surface as shown in FIG. 1 was fabricated by cutting, and the surface of the fabricated metal member 50 was cleaned by acid etching.

### (2) Formation of First Resin Layer

A general-purpose press machine was used to shape a resin sheet (i.e., first sheet) on top of the metal member 50 to form a first resin layer 10. The resin sheet was made of epoxy resin sheet (with a thickness of 70 μm, a melting temperature of 100° C., and a curing temperature of 170° C.).

A lower half of a die (i.e., metal member 50) and an upper half of the die, made of aluminum, were installed on the press machine, and a resin sheet was sandwiched between the lower and upper halves of the die to perform press working. The thickness of the cavity formed between the lower and upper halves of the die when being engaged was 0 mm. A state with a maximum pressure during pressing of 3 MPa and a die temperature of 200° C. was kept for five minutes and, thereafter, the lower and upper halves of the die as engaged were removed from the press machine. After air cooling, the upper half of the die was removed to provide a metal member 50 with a first resin layer 10 formed thereon, that is, a substrate 70. The first resin layer 10 was formed from an epoxy resin and had a thickness of 70 μm, the same as for the resin sheet.

### (3) Formation of First Circuit Wiring

For the present inventive example, the first circuit wiring 20 formed from plating film on top of the first resin layer 10 was formed by the following method.

### (a) Formation of Catalytic-Activity Inhibitor Layer

A catalytic-activity inhibitor layer containing a hyperbranched polymer represented by formula (1) provided below, which is a catalytic-activity inhibitor agent, was formed on the surface 10a of the first resin layer 10. The hyperbranched polymer represented by formula (1) was synthesized by the method disclosed in WO 2018/131492 A1. In formula (1), R0 indicates a vinyl group or an ethyl group.

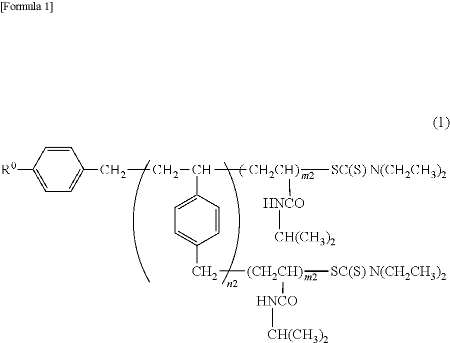

The molecular weight of the synthesized hyperbranched polymer was measured by gel permeation chromatography (GPC). The molecular weight was 9946 in terms of number-average molecular weight (Mn), and 24,792 in terms of weight-average molecular weight (Mw), which are significantly different values from the number-average molecular weight (Mn) and weight-average molecular weight (Mw) specific to a hyperbranched structure.

The synthesized polymer represented by Formula (1) was dissolved in methyl ethyl ketone to prepare a polymer solution with a polymer concentration of 0.5 weight %. The substrate was immersed in the polymer solution at room temperature for five seconds, and then dried in a 100° C. drier for 10 minutes. This formed a catalytic-activity inhibitor layer on the surface of the surface 70. The thickness of the catalytic-activity inhibitor layer was 100 nm.

### (b) Laser Drawing

The region of the surface 10a of the first resin layer 10 where the first circuit wiring 20 was to be formed (i.e., wiring region 10A) was illuminated with a laser beam. A UV laser (from Keyence Corporation) was used to perform laser drawing with a power of 80%, at a speed of 300 mm/s and a frequency of 40 kHz to draw a grid-shaped pattern with a pitch of 20 μm.

The laser drawing removed the portions of the catalytic-activity inhibitor layer located on the wiring region 10A and, at the same time, roughened the wiring region 10A. Further, laser-drawing conditions were adjusted to regulate the surface roughness Rz of the overlap region 10C, Rz of the region (10A-10C), and the minimum distance t to predetermined values. The values determined by SEM cross-section observation, discussed further below, are shown in Table 1.

### (c) Formation of Plating Film

The substrate 70 was immersed, for five minutes, in a commercially available aqueous solution of palladium chloride (PdCl₂) (“Activator” from Okuno Chemical Industries Co., Ltd.) regulated to 30° C. Thereafter, the substrate was removed from the aqueous solution of palladium chloride, and water washed.

The substrate 70 was immersed, for 10 minutes, in an electroless nickel-phosphorus plating solution (“Top Nicoron LPH-L” from Okuno Chemical Industries Co., Ltd.; pH: 6.5) regulated to 60° C. An electroless nickel-phosphorus plating film of about 1 μm grew on top of the laser drawing-affected portion of the first resin layer 10 (i.e., wiring region 10A).

On top of the electroless nickel-phosphorus plating film were further deposited, in this order: a copper electroplating film of 20 μm; and a gold electroplating film of 0.1 μm, thus forming the first circuit wiring 20.

### (4) Mounting of First Mounted Components

The first mounted component 30 used was a surface-mount-type high-brightness LED (NS2W123BT from Nichia Corporation, 3.0 mm by 2.0 mm by 0.7 mm (height)). First, as shown in FIG. 1, three first mounted components 30 were placed on top of the first circuit wiring 20, with solder 40 at room temperature provided in between. Next, the substrate with the LED provided thereon was loaded into a reflow furnace (solder reflow). The substrate was heated inside the reflow furnace, where the highest end-point temperature of the substrate was 240° C. to 260° C., and the time period for which the substrate was heated at the highest end-point temperature was about one minute. The first mounted components 30 were mounted on the first resin layer 10 by means of solder to provide a circuit part 100 for the present inventive example, as shown in FIG. 1.

### Inventive Example 2

For the present inventive example, the first resin layer 10 was formed not by shaping but by applying a resin liquid (i.e., first resin liquid) to the metal member 50. Otherwise, a circuit part 100 as shown in FIG. 1 was fabricated by the same method as for Inventive Example 1.

To the metal member 50 fabricated in the same manner as for Inventive Example 1 was applied a first resin liquid constituted by an epoxy paint using a spray coater. After application, the member was dried at 170° C. for one hour to provide a metal member 50 with a first resin layer 10 formed thereon, i.e., substrate 70. The thickness of the first resin layer (i.e., epoxy resin layer) was 70 μm.

Thereafter, in the same manner as for Inventive Example 1, first circuit wiring 20 was formed and first mounted components 30 were mounted to provide a circuit part 100 for the present inventive example.

### Inventive Examples 3 and 4

For Inventive Examples 3 and 4, laser-drawing conditions were adjusted to change the surface roughness Rz of the overlap region 10C and the minimum distance t from the values of Inventive Example 1 to different predetermined values. Further, for Inventive Example 4, the surface roughness Ra of the overlap region 10C was changed from the value of Inventive Example 1 to a different predetermined value. The values determined by SEM cross-section observation discussed further below are shown in Table 1. Otherwise, circuit parts 100 as shown in FIG. 1 were fabricated by the same method as for Inventive Example 1.

### Inventive Example 5

For the present inventive example, a circuit part 300 as shown in FIG. 7 was fabricated. The circuit part 300 included a second resin layer 110, second circuit wiring 120 containing plating film, and a second mounted component 130. Otherwise, the circuit part 300 had generally the same construction as the circuit part 100 for Inventive Example 1.

First, a metal member 50 was fabricated, a first resin layer 10 was formed (i.e., shaped) and first circuit wiring 20 was formed by the same method as for Inventive Example 1. Next, a second resin layer 110 was formed on portions of the surface 10a of the first resin layer 10 other than the overlap region 10C. The second resin layer 110 was formed by the same method as for the first resin layer 10 of Inventive Example 2, that is, by applying an epoxy paint (i.e., second resin liquid) and then drying. The second resin layer 110 was first formed over the entire surface 10a inclusive of the overlap region 10C and, thereafter, the portions of the second resin layer 110 located on the overlap region 10C were removed by laser-beam illumination. The second resin layer 110 was formed from an epoxy resin, and had a thickness of 70 μm.

Second circuit wiring 120 was formed on top of the second resin layer 110 and, thereafter, first mounted components 30 and a second mounted component 130 were mounted to provide a circuit part 300 for the present inventive example. The second circuit wiring 120 was formed by the same method as for the first circuit wiring 20 for Inventive Example 1. The first and second mounted components 30 and 130 were mounted by the same method as for the first mounted component 30 of Inventive Example 1.

### Inventive Example 6

For the present inventive example, a circuit part 300 as shown in FIG. 7 was fabricated. For the present inventive example, a first resin layer 10 was formed by the same method as for Inventive Example 2, that is, by applying an epoxy paint (i.e., first resin liquid) and then drying. Otherwise, a circuit part 300 was fabricated by the same method as for Inventive Example 5.

### Inventive Example 7

For the present inventive example, a circuit part 200 as shown in FIG. 4 was fabricated. The circuit part 200 included a second resin layer 110. Otherwise, the circuit part 200 had the same construction as the circuit part 100 for Inventive Example 1.

First, a metal member 50 was fabricated, a first resin layer 10 was formed (i.e., shaped) and first circuit wiring 20 was formed by the same method as for Inventive Example 1. Next, a second resin layer 110 was formed on portions of the surface 10a of the first resin layer 10 other than the overlap region 10C. The second resin layer 110 was formed by the same method as for the first resin layer 10 for Inventive Example 2, that is, by applying an epoxy paint (i.e., second resin liquid) and then drying. The second resin layer 110 was first formed over the entire surface 10a inclusive of the overlap region 10C and, thereafter, the portions of the second resin layer 110 located on the overlap region 10C were removed by laser-beam illumination. The second resin layer 110 was formed from an epoxy resin, and had a thickness of 70 μm. Thereafter, first mounted components 30 were mounted by the same method as for Inventive Example 1 to provide a circuit part 200 for the present inventive example.

### Inventive Example 8

For the present inventive example, a circuit part 100 was fabricated that included a radiation layer (not shown) provided on portions of the surface of the metal member 50 where the first resin layer 10 was not present. It had generally the same construction as the circuit part 100 for Inventive Example 1 except for having a radiation layer.

First, a metal member 50 was fabricated by the same method as for Inventive Example 1. Next, a radiation layer was formed on the surface of the metal member 50 by electrodeposition coating. Thereafter, a first resin layer 10 was formed (i.e., shaped), first circuit wiring 20 was formed and first mounted components 30 were mounted by the same method for Inventive Example 1 to provide a circuit part 100 for the present inventive example.

### Comparative Examples 1 and 2

For each of Comparative Examples 1 and 2, a first resin layer 10 was formed by insert molding (i.e., transfer molding). The first resin layer 10 was formed from an epoxy resin, and had a thickness of 200 μm. Further, laser drawing conditions were adjusted to change the surface roughness Rz of the overlap region 10C and the minimum distance t from the values of Inventive Example 1 to different predetermined values. The values determined by SEM cross-section observation discussed further below, are shown in Table 1. Otherwise, a circuit part 100 as shown in FIG. 1 was fabricated by the same method as for Inventive Example 1.

### Evaluation of Circuit Part

The circuit parts fabricated for Inventive Examples 1 to 8 and Comparative Examples 1 to 2 described above were evaluated as specified below. The evaluation results are shown in Table 1.

### (1) Heat Dissipation Testing of Circuit Part

For each of the circuit parts fabricated for Inventive Examples 1 to 8 and Comparative Examples 1 to 2, a thermocouple was bonded to an end of a mounted component (i.e., LED) 30, a certain level of electric current (0.8 A) was passed through the LED 30 to turn it on and, 30 minutes after turn-on, the temperature of the LED 30 was measured. The average of the temperatures of all the LEDs 30 on the circuit part was calculated, and the heat dissipation of the circuit part was evaluated in accordance with the following criteria of evaluation.

### <Criteria of Evaluation of Heat Dissipation of Circuit Part>

A: The LED surface temperature 30 minutes after turn-on was not higher than 95° C.
B: The LED surface temperature 30 minutes after turn-on was above 95° C. and below 130° C.
C: The LED surface temperature 30 minutes after turn-on was not lower than 130° C.

### (2) Insulation Testing 1 for Insulating Resin Layer

Separately from the circuit parts fabricated for Inventive Examples 1 to 8 and Comparative Examples 1 to 2, samples for insulation testing 1 for the inventive and comparative examples were fabricated. The samples for insulating testing 1 had the same construction as the circuit parts fabricated for the inventive and comparative examples except that no first and second mounted components 30 and 130 were mounted.

For each sample for insulation testing 1, a voltage of 100 V was applied between the first circuit wiring 20 and the metal member 50, the resistance between the first circuit wiring 20 and metal member 50 was measured using a tester, and the insulation of the insulating resin layer was evaluated based on the following criteria of insulation evaluation 1.

### <Criteria of Insulation Evaluation 1>

A: The resistance between the first circuit wiring 20 and the metal member 50 was above 10000 MΩ.
B: The resistance between the first circuit wiring 20 and the metal member 50 was 100 to 10000 MΩ.
C: The resistance between the first circuit wiring 20 and the metal member 50 was below 100 MΩ.

### (3) Insulation Testing 2 for Insulating Resin Layer

Separately from the circuit parts fabricated for Inventive Examples 1 to 8 and Comparative Examples 1 to 2, samples for insulation testing 2 for the inventive and comparative examples were fabricated. The samples for insulating testing 2 had the same construction as the circuit parts fabricated for the inventive and comparative examples except that no first and second mounted components 30 and 130 were mounted.

For each sample for insulation testing 2, the withstand voltage between the first circuit wiring 20 and metal member 50 was measured using a withstand voltage insulation resistance tester 5300 (from Kikusui Electronics Corp.), and the withstand voltage of the insulating resin layer was evaluated based on the criteria of insulation evaluation 2.

### <Criteria of Insulation Evaluation 2>

A: The withstand voltage between the first circuit wiring 20 and the metal member 50 was not lower than 1.5 kV.
B: The withstand voltage between the first circuit wiring 20 and the metal member 50 was above 0.5 kV and below 1.5 kV.
C: The withstand voltage between the first circuit wiring 20 and the metal member 50 was not higher than 0.2 kV.

### (4) Adhesion Testing for Circuit Wiring (Plating Film)

Separately from the circuit parts fabricated for Inventive Examples 1 to 8 and Comparative Examples 1 to 2, samples for adhesion testing for the inventive and comparative examples were fabricated. The samples for adhesion testing had the same construction as the circuit parts fabricated for the inventive and comparative examples except that no first and second mounted components 30 and 130 were mounted.

First, for each sample for adhesion testing, a straight portion of the first circuit wiring 20 on the first resin layer 10 was cut off the other portions. An end of the cut straight portion was pinched for tensile testing, the straight portion was peeled off the first resin layer 10 to measure the peeling resistance, and the adhesive strength per unit width was calculated.

### <Criteria of Adhesion Evaluation>

A: The adhesive strength of the plating film was not lower than 10 N/cm.
B: The adhesive strength of the plating film was not lower than 5 N/cm and below 10 N/cm.
C: The adhesive strength of the plating film was below 5 N/cm.

### (5) Cross-Section Observation for Circuit Part

Separately from the circuit parts fabricated for Inventive Examples 1 to 8 and Comparative Examples 1 to 2, samples for cross-section observation for the inventive and comparative examples were fabricated. The samples for cross-section observation had the same construction as the circuit parts fabricated for the inventive and comparative examples except that no first and second mounted components 30 and 130 were mounted.

Each sample for cross-section observation was cut to expose a cross section of the wiring region 10A inclusive of the overlap region 10C, which was polished, and then the cross section was observed by SEM. Similarly, a sample for cross-section observation was cut to expose a cross section of the wiring-free region 10D, which was polished, and then the cross section was observed by SEM. Two different locations were observed at a magnification of 200 times. From this cross-section observation were determined: the surface roughness Rz and surface roughness Ra of the overlap region 10C; the minimum distance t from the overlap region 10C to the face 10b of the first resin layer 10 facing the metal member 50; the surface roughness Rz and surface roughness Ra of the region (10A-10C); and the surface roughness Rz of the wiring-free region 10D. The results are shown in Table 1.

TABLE 1

| | | Inventive examples | | | | | | | | | | | | | | | | Comparative ex. | | | |
|---|---|---|---|---|---|---|---|---|---|---|---|---|---|---|---|---|---|---|---|---|---|
| | | 1 | | 2 | | 3 | | 4 | | 5 | | 6 | | 7 | | 8 | | 1 | | 2 | |
| Rz | 10C*¹ | 20 | μm | 20 | μm | 30 | μm | 15 | μm | 20 | μm | 20 | μm | 20 | μm | [symbol] 0 | μm | 20 | μm | 150 | μm |
| | (10A-10C)*² | 10 | μm | 10 | μm | 10 | μm | 10 | μm | 10 | μm | 10 | μm | 10 | μm | 10 | μm | 10 | μm | 10 | μm |
| | 10D*³ | 1 | μm | 1 | μm | 1 | μm | 1 | μm | 1 | μm | 1 | μm | 1 | μm | 1 | μm | 1 | μm | 1 | μm |
| Ra | 10C*¹ | 3.6 | μm | 3.6 | μm | 3.6 | μm | 2.3 | μm | 3. [symbol] | μm | 3. [symbol] | μm | 3. [symbol] | μm | 4.5 | μm | [symbol] | μm | 14.8 | μm |
| | (10A-10C)*² | 2.1 | μm | 2.1 | μm | 2.1 | μm | 2.1 | μm | 2.1 | μm | 2.1 | μm | 2.1 | μm | 2.1 | μm | 2.1 | μm | 2.1 | μm |

| | | | | | | | | | | | | | | | | | | | | |
|---|---|---|---|---|---|---|---|---|---|---|---|---|---|---|---|---|---|---|---|---|
| Distance [symbol] *⁴ | 20 | μm | 20 | μm | 10 | μm | 30 | μm | 20 | μm | 2 [symbol] | μm | 20 | μm | 10 | μm | 170 | μm | 10 | μm |
| Thickness 10d*⁵ | 70 | μm | 70 | μm | 70 | μm | 70 | μm | 70 | μm | 70 | μm | 70 | μm | 70 | μm | 200 | μm | 200 | μm |

| | | | | | | | | | | |
|---|---|---|---|---|---|---|---|---|---|---|
| Heat dissipation | B | B | A | B | B | B | B | A | C | C |
| (Temperature) | (100° C.) | (100° C.) | (95° C.) | (1 [symbol] ° C.) | (100° C.) | (100° C.) | (100° C.) | (95° C.) | (130° C.) | (1 [symbol] 0° C.) |
| Insulating property 1 | A | A | A | A | A | A | A | A | A | C |
| (Resistance) | [symbol] | [symbol] | [symbol] | [symbol] | [symbol] | [symbol] | [symbol] | [symbol] | [symbol] | [symbol] |
| Insulating property 2 | A | A | B | A | A | A | A | B | A | C |
| (Withstand voltage) | (1. [symbol] kV) | (1.5 kV) | (1.0 kV) | (2.0 kV) | (1.5 kV) | (1.5 kV) | (1.5 kV) | (1.0 kV) | ( [symbol] kV) | (0.2 kV) |
| Adhesive strength | B | B | A | B | B | B | B | A | B | A |
| | (7 N/cm) | (7 N/cm) | (10 N/cm) | ( [symbol] N/cm) | (7 N/cm) | (7 N/cm) | (7 N/cm) | (10 N/cm) | (7 N/cm) | (20 N/cm) |

*¹Overlap region 10C being the overlap between the wiring region 10A where the first circuit wiring 20 is present and the mount region 10B where the first mounted component [symbol] is mounted
*²Wiring region 10A other than the overlap region 10C.
*³Wiring-free region 10D where the first circuit wiring 20 is not present
*⁴Minimum distance t from the overlap region 10C to the face 10B of the first resin layer 10 facing the metal member 50
*⁵Thickness of the first resin layer 10 [symbol]
indicates data missing or illegible when filed

As shown in Table 1, for each of the circuit parts fabricated for Inventive Examples 1 to 8, all the evaluation results, i.e., heat dissipation, insulating properties (i.e., resistance and withstand voltage) and adhesive strength, were good. Further, for each of the circuit parts fabricated for Inventive Examples 1 to 7, a small amount of plating film, although practically not enough to cause a problem, precipitated on the surface of the metal member. In contrast, for Inventive Example 8, no plating film precipitated on the surface of the metal member of the circuit part, which included a radiation layer. These results demonstrate that the radiation layer increases the heat dissipation of the circuit part and, at the same time, prevents precipitation of electroless-plating film on the surface of the metal member.

On the other hand, Comparative Example 1 with a minimum distance t of 170 μm had low heat dissipation. Comparative Example 2, where the surface roughness Rz of the overlap region 10C was 150 μm, had low heat dissipation and poor insulating properties (i.e., resistance and withstand voltage).

### Inventive Example 9

For the present inventive example, a circuit part 400 as shown in FIG. 9 was fabricated. For the present inventive example, the metal member 450 used was a product of sheet metal working. Further, first mounted components 30 were mounted on a plurality of faces of the substrate 470. The first mounted components 30 used were power semiconductor devices capable of passing 1.5 A of electric current. The terminal pitch of the power semiconductor devices was 50 μm.

### (1) Preparation of Metal Member

A thin sheet of aluminum (aluminum A1050) was subjected to sheet metal working to fabricate a hollow, sheet-shaped metal member 450 with an opening at the bottom. To increase the adhesive strength between the metal member 450 and a first resin layer 10 to be formed thereon, the region where the first resin layer 10 was to be formed was roughened by a laser.

### (2) Formation of First Resin Layer

An epoxy paint containing spherical alumina particles with a particle diameter of 1 to 10 μm in 70 volume % was applied to the roughened region of the fabricated metal member 50 using a spray coater. After application, the member was dried at 150° C. for five hours to provide a metal member 450 provided with a first resin layer 10, i.e., substrate 470. The film thickness of the first resin layer was measured at five locations within the region where first circuit wiring (i.e., plating film) 20 was expected to be formed (i.e., wiring region 10A). The average film thickness was 90 μm, where the measurements at the five locations were within a range of 79 μm to 101 μm (within a range of the average film thickness of 90 μm±12%.

### (3) Formation of First Circuit Wiring

### (a) Formation of First Groove

A first groove 11 was formed by laser drawing in the wiring region 10A of the first resin layer 10 (see FIG. 11(a)). The laser drawing used a UV laser (from Keyence Corporation) at a speed of 20 mm/s, with a power of 80%, and at a frequency of 100 kHz. The first groove 11 was formed across the entire extension of the wiring region 10A.

### (b) Formation of Catalytic-Activity Inhibitor Layer and Formation of Second Groove

A catalytic-activity inhibitor layer 80 was formed on the surface 10a of the first resin layer 10 by the same method as for Inventive Example 1 (see FIG. 11(b)). Although FIG. 11(b) shows the catalytic-activity inhibitor layer 80, in reality, the layer had a thickness of 100 nm or less, i.e., was too thin to be visible.

The substrate 470 was fixed in position with alignment pins (not shown), and laser drawing was performed under the same laser drawing conditions that were used to form the first groove 11 to form a second groove 12 inside the first groove 11 (see FIG. 11(c)). Similar to the first groove 11, the second groove 12 was formed across the entire extension of the wiring region 10A. This resulted in a two-stage groove structure 13 composed of first and second grooves 11 and 12. Further, the laser drawing removed the portions of the catalytic-activity inhibitor layer 80 located in the region where the second groove 12 was present.

### (c) Formation of Plating Film

An electroless-plating catalyst was provided in the same manner as for Inventive Example 1. Next, the substrate 470 was immersed, for five minutes, in an electroless nickel-phosphorus plating solution (“Top Nicoron LTN” from Okuno Chemical Industries Co., Ltd.) regulated to 60° C. An electroless nickel-phosphorus plating film 61 (i.e., foundation plating film) of about 1 μm grew on the bottom of the second groove 12, while almost no growth of electroless-plating film was found on the sides of the first groove 11 (see FIG. 11(d)). Electroplating was then performed to form a copper electroplating film 62 of 70 μm. A portion of the copper electroplating film 62 protruded outward from the two-stage groove structure 13 to form a protrusion 64 (see FIG. 12). Further, for the present inventive example, some portions of the wiring (i.e., plating film) that had joined together during electroplating were cut off by machining to provide a desired circuit pattern (i.e., first circuit wiring 20).

### (4) Formation of Second Resin Layer and Mounting of First Mounted Components

A second resin layer 110 was formed by the same method as for Inventive Example 7 and first mounted components 30 were mounted, thus providing a circuit part 400 for the present inventive example.

### <Construction and Evaluation of Fabricated Circuit Part>

The sizes of the two-stage groove structure 13 and plating film 60 of the circuit part 400 are indicated below. It is to be noted that the line width of the first circuit wiring 20 fabricated for the present inventive example was not constant. The following shows values for the portion with the smallest line width of the first circuit wiring 20.

### See FIG. 11(a)

Width 11d of first groove 11 (width of two-stage groove structure 13): 40 μm
Depth 11D of first groove 11: 40 μm
Distance (minimum value) 11A between adjacent first grooves 11: 40 μm

### See FIG. 11(c)

Width 12d of second groove 12: 25 μm
Depth 12D of second groove 12: 20 μm
Depth 13D of two-stage groove structure 13: 60 μm
(Care was taken to ensure that the distance 12a between a side of the first groove 11 and the associated side of the second groove 12 was 5 μm or more.)

### See FIG. 12

Film thickness 60D of plating film 60: 70 μm
Height 64h of protrusion 64: 10 μm
Width 60d of plating film 60 (line width of first circuit wiring 20): 50 μm
Dimension 64d of portion of protrusion 64 protruding from two-stage groove structure 13 as measured in the line-width direction: 5 μm
Space 14 between wiring lines: 30 μm

In the circuit part 400, the height 64h of the protrusion 64 as measured from portions of the surface 10a of the first resin layer 10 where the first circuit part 20 (10 μm) was not present was about 14% of the film thickness 60D of the plating film 60 (70 μm).

The protrusion 64 protruded from the two-stage groove structure 13 in the direction of the line width of the first circuit wiring 20. However, the dimension 64d of the portion of the protrusion 64 protruding from the two-stage groove structure 13 in the line-width direction along the surface 10a of the first resin layer 10 (5 μm) was 10% of the line width 60d of the first circuit wiring 20 (50 μm). The distance 11A between adjacent first grooves 11 of 40 μm ensured that the inter-line space 14 was 30 μm.

The ratio of the film thickness 60D of the plating film 13 of the first circuit wiring 20 (70 μm) to the line width 60d of the first circuit wiring 20 (50 μm), (60D/60d), was 1.4. The first circuit wiring 20 had a high aspect ratio with a sufficiently large film thickness of the plating film relative to the line width. The present inventive example provided both a reduction of the line width of the first circuit wiring 20 and an increase of the film thickness of the plating film 60.

It was demonstrated that, when a maximum current of 1.5 A was passed through the circuit part 400, the part operated without a problem.

### Comparative Example 3

For the present comparative example, it was attempted to fabricate a circuit part 700 as shown in FIGS. 14(a) to 14(c). The circuit part 700 had generally the same construction as the circuit part 400 for Inventive Example 9 except that a groove 711 constituted by a one-stage groove structure, instead of the two-stage groove structure 13, was formed in the surface 10a of the first resin layer 10.

First, a substrate 470 was fabricated by the same method as for Inventive Example 9 and a catalytic-activity inhibitor layer 80 was formed on the surface 10a of the first resin layer 10. Next, a groove 711 was formed by laser drawing. The laser drawing removed the portions of the catalytic-activity inhibitor layer 80 located inside the groove 711. The groove 711 was sized as follows:
Width 711d of groove 711: 40 μm
Depth 711D of groove 711: 40 μm
Distance (minimum value) 711A between adjacent grooves 711: 40 μm

Next, electroless plating was performed by the same method as for Inventive Example 9. This resulted in electroless-plating film 761 across the entire groove 711, inclusive of the sides of the groove 711 (see FIG. 14(a)).

Next, electroplating was performed by the same method as for Inventive Example 9. As shown in FIG. 14(b), halfway through the electroplating, thick electroplating film 762 was formed on the edges 711a (i.e., corners) of the opening of each groove 711. For the present comparative example, electroless-plating film 761 was formed across the entire groove 711 inclusive of the edges 711a, where electrolytic concentration can easily occur. This is assumed to have resulted in thick electroplating film 762 at and near the edges 711a and caused unevenness in the thickness of the electroplating film. Thereafter, electroplating was performed until the film thickness 760D of the plating film 760 was approximately 70 μm to form first circuit wiring 720 (see FIG. 14(c)).

In the first circuit wiring 720, the plating film 760 significantly protruded outward from the groove 711 to form a protrusion 764. The protrusion 764 joined adjacent wiring lines, making it impossible to retain insulation of lines from one another. The height 764h of the protrusion 764 was 30 μm, about 43% of the film thickness 760D (70 μm) of the plating film 760. Thus, for the present comparative example, sufficiently functioning first circuit wiring 720 could not be formed; fabrication of the circuit part 700 was halted at this point.

### Industrial Applicability

The circuit part according to the present invention has high heat dissipation. Accordingly, the circuit part according to the present invention is suitable as a part with mounted components such as LEDs mounted thereon, and is applicable as a smartphone or automotive part.

### REFERENCE SIGNS LIST

10: first resin layer
11: first groove
12: second groove
13: two-stage groove structure (multi-stage groove structure)
20: first circuit wiring
30: first mounted components
40: solder
50, 450, 550: metal member
60: plating film
70, 470, 570: substrate
100, 200, 300, 400, 500: circuit part (three-dimensional circuit part)
110: second resin layer
120: second circuit wiring
130: second mounted component
560: reinforcement member

1. A three-dimensional circuit part comprising:
a metal member;
a first resin layer provided on top of the metal member;
first circuit wiring including plating film provided on a wiring region of a surface of the first resin layer; and
a first mounted component mounted on a mount region of the surface of the first resin layer to electrically connect to the first circuit wiring,
wherein:
in the surface of the first resin layer, the wiring region and the mount region overlap in an overlap region, and a surface roughness Rz of the overlap region is 10 μm to 120 μm;
a minimum distance between the first circuit wiring and a face of the first resin layer facing the metal member within the overlap region is 10 m to 100 μm; and
wherein a surface roughness Ra of the overlap region is higher than a surface roughness Ra of a portion of the wiring region other than the overlap region.

2. The three-dimensional circuit part according to claim 1, wherein the surface roughness Rz of the overlap region is higher than a surface roughness Rz of a portion of the wiring region other than the overlap region.

3. (canceled)

4. The three-dimensional circuit part according to claim 1, further comprising:
a second resin layer provided on a portion of the surface of the first resin layer other than the overlap region to cover the first circuit wiring,
wherein a ratio of a surface roughness Rz of a portion of the wiring region other than the overlap region to the surface roughness Rz of the overlap region is not higher than 1/2.

5. The three-dimensional circuit part according to claim 1, further comprising:
a second resin layer provided on a portion of the surface of the first resin layer other than the overlap region to cover the first circuit wiring;
second circuit wiring including plating film provided on top of the second resin layer; and
a second mounted component mounted on top of the second resin layer to electrically connect to the second circuit wiring.

6. The three-dimensional circuit part according to claim 1, wherein the first resin layer contains a thermosetting resin.

7. The three-dimensional circuit part according to claim 6, wherein the thermosetting resin is an epoxy resin.

8. The three-dimensional circuit part according to claim 1, wherein the metal member is a product of sheet metal working.

9. The three-dimensional circuit part according to claim 8, wherein a material forming the product of sheet metal working is one selected from the group consisting of aluminum, stainless steel, and copper.

10. A three-dimensional circuit part comprising:
a metal member;
a first resin layer provided on top of the metal member;
first circuit wiring including plating film provided on a wiring region of a surface of the first resin layer; and
a first mounted component mounted on a mount region of the surface of the first resin layer to electrically connect to the first circuit wiring,
wherein:
the first resin layer includes a multi-stage groove structure including a first groove formed in the wiring region and a second groove formed within the first groove and having a smaller width than the first groove;
the plating film of the first circuit wiring fills the multi-stage groove structure; and
wherein the plating film of the first circuit wiring includes a protrusion protruding outward from the multi-stage groove structure,
wherein a height of the protrusion as measured from a portion of the surface of the first resin layer where the first circuit wiring is not present is not larger than 30% of a film thickness of the plating film.

11. (canceled)

12. The three-dimensional circuit part according to claim 11, wherein the protrusion protrudes from the first groove in a line-width direction of the first circuit wiring to extend along the surface of the first resin layer,
wherein a length of a portion of the protrusion that protrudes from the first groove in the line-width direction as measured along the surface of the first resin layer is not larger than 30% of a line width of the first circuit wiring.

13. The three-dimensional circuit part according to claim 10, wherein:
a ratio of a film thickness of the plating film of the first circuit wiring to a line width of the first circuit wiring is 0.3 to 4; and
the film thickness of the plating film of the first circuit wiring is 15 to 100 μm.

14. A method of manufacturing the three-dimensional circuit part according to claim 1, comprising:
preparing the metal member;
forming the first resin layer by shaping a first resin sheet on top of the metal member or applying a first resin liquid to the metal member;
forming the first circuit wiring through plating on the wiring region of the surface of the first resin layer; and
mounting the first mounted component on the mount region of the surface of the first resin layer.

15. The manufacturing method according to claim 14, further comprising:
before mounting the first mounted component, forming a second resin layer on a portion of the surface of the first resin layer other than the overlap region to cover the first circuit wiring,
wherein the second resin layer is formed by shaping a second resin sheet on top of the first resin layer or applying a second resin liquid to the first resin layer.

16. The manufacturing method according to claim 15, wherein the second resin layer is formed by applying the second resin liquid to the first resin layer.

17. The manufacturing method according to claim 14, wherein the forming of the first circuit wiring includes:
illuminating the wiring region with a laser beam to roughen the wiring region;
providing the roughened wiring region with an electroless-plating catalyst; and
forming electroless-plating film by bringing an electroless-plating solution into contact with the wiring region provided with the electroless-plating catalyst.

18. The manufacturing method according to claim 17, wherein the forming of the first circuit wiring further includes:
before illuminating the wiring region with the laser beam, forming a layer containing a catalytic-activity inhibitor agent on the surface of the first resin layer inclusive of the wiring region,
wherein a portion of the layer containing the catalytic-activity inhibitor agent located on the wiring region is removed by illuminating the wiring region with the laser beam.

19. The manufacturing method according to claim 14, wherein the forming of the first circuit wiring includes:
forming a first groove in the wiring region through illumination with a laser beam or press working;
forming a layer containing a catalytic-activity inhibitor agent on the surface of the first resin layer inclusive of the wiring region;
forming a second groove with a smaller width than the first groove by directing a laser beam into the first groove;
providing the wiring region with an electroless-plating catalyst; forming electroless-plating film within the second groove by bringing an electroless-plating solution into contact with the wiring region provided with the electroless-plating catalyst; and
forming electroplating film on top of the electroless-plating film.

20. The manufacturing method according to claim 14, wherein the preparing of the metal member is forming the metal member through metal sheet working of a metal sheet.

21. The manufacturing method according to claim 20, wherein a material of the metal sheet is one selected from the group consisting of aluminum, stainless steel, and copper.
